(19) United States
(12) Patent Application Publication
(10) Pub. No.: US 2026/0107775 A1
(43) Pub. Date: Apr. 16, 2026

(54) CRACK-STOP METALLIC STRUCTURES FOR COMPOSITE PACKAGES AND METHODS OF FORMING THE SAME

(71) Applicant: Taiwan Semiconductor Manufacturing Company Limited, Hsinchu (TW)

(72) Inventors: Tzuan-Horng Liu, Longtan Township (TW); An-Jhih Su, Taoyuan City (TW); Yen-Liang Lin, Taichung City (TW); Po-Yuan Teng, Hsinchu City (TW); Tsung-Yuan Yu, Taipei City (TW); Chih-Hao Chang, Xinpu Township (TW); Che-Hsiang Hsu, Taichung City (TW); Chung-Ming Weng, Taichung City (TW)

(21) Appl. No.: 18/912,652

(22) Filed: Oct. 11, 2024

(51) Int. Cl. H01L 23/00; H01L 21/48; H01L 21/56; H01L 23/31; H01L 23/48; H01L 23/498; H01L 25/16

(52) U.S. Cl. CPC H10W 42/121; H10W 20/20; H10W 70/05; H10W 70/095; H10W 70/65; H10W 74/016; H10W 74/114; H10W 90/401; H10W 74/10; H10W 74/15; H10W 90/00; H10W 90/724; H10W 90/734

(57) ABSTRACT

A device structure may be formed by: providing a first redistribution structure; disposing a metallic crack-stop structure comprising at least one metallic pillar over a peripheral region of the first redistribution structure; attaching a connection die to a center region of the first redistribution structure; forming an encapsulation frame around the connection die and the metallic crack-stop structure; and forming a second redistribution structure over the connection die, the metallic crack-stop structure, and the encapsulation frame.

### BACKGROUND

Cracks may develop in composite interposers including different types of material such as molding compounds and redistribution dielectric layers. Suppression of such cracks is desired to enhance reliability of composite interposers.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. The dimensions of the various features may be arbitrarily increased or reduced for clarity of discussion.

FIG. 1 is a vertical cross-sectional view of an exemplary structure after attaching a semiconductor die and a dummy die to a first carrier wafer according to an embodiment of the present disclosure.

FIG. 2 is a vertical cross-sectional view of the exemplary structure after formation of a molding compound die frame according to an embodiment of the present disclosure.

FIG. 3 is a vertical cross-sectional view of the exemplary structure after formation of a first redistribution structure according to an embodiment of the present disclosure.

FIG. 4 is a vertical cross-sectional view of the exemplary structure after disposing through-interposer via (TIV) structures on the first redistribution structure according to an embodiment of the present disclosure.

FIG. 5 is a vertical cross-sectional view of the exemplary structure after disposing a metallic crack-stop structure on the first redistribution structure according to an embodiment of the present disclosure.

FIG. 6 is a vertical cross-sectional view of the exemplary structure after attaching a connection die to a center region of the first redistribution structure according to an embodiment of the present disclosure.

FIGS. 7A-7J are top down views of various configurations of the exemplary structure after the processing steps of FIG. 6.

FIG. 8 is a vertical cross-sectional view of the exemplary structure after applying an underfill material between the first redistribution structure and the connection die according to an embodiment of the present disclosure.

FIG. 9 is a vertical cross-sectional view of the exemplary structure after formation of an encapsulation frame according to an embodiment of the present disclosure.

FIG. 10 is a vertical cross-sectional view of the exemplary structure after formation of a second redistribution structure according to an embodiment of the present disclosure.

FIG. 11 is a vertical cross-sectional view of the exemplary structure after attaching a second carrier wafer to the second redistribution structure and detaching the first carrier wafer from the composite die according to an embodiment of the present disclosure.

FIG. 12 is a magnified view of a region of the exemplary structure around a dicing channel during a dicing process according to an embodiment of the present disclosure.

FIG. 13 is a vertical cross-sectional view of a composite package that is formed by dicing a reconstituted wafer of the exemplary structure of FIG. 11 according to an embodiment of the present disclosure.

FIG. 14 is a vertical cross-sectional view of an in-process semiconductor interposer within a wafer including an array of in-process semiconductor interposers according to an embodiment of the present disclosure.

FIG. 15 is a vertical cross-sectional view of an assembly including an in-process semiconductor interposer, the composite package, and two high bandwidth memory dies within a unit area of the wafer according to an embodiment of the present disclosure.

FIG. 16 is a vertical cross-sectional view of the assembly after formation of a molding compound multi-die frame according to an embodiment of the present disclosure.

FIG. 17 is a vertical cross-sectional view of the assembly after thinning the backside of the wafer and after dicing a reconstituted wafer into an integrated semiconductor package according to an embodiment of the present disclosure.

FIG. 18 is a first flowchart illustrating steps for forming a device structure according to an embodiment of the present disclosure.

FIG. 19 is a second flowchart illustrating steps for forming a device structure according to an embodiment of the present disclosure.

FIG. 20 is a third flowchart illustrating steps for forming a device structure according to an embodiment of the present disclosure.

### DETAILED DESCRIPTION

The following disclosure provides many different embodiments, or examples, for implementing different features of the provided subject matter. Specific examples of components and arrangements are described below to simplify the present disclosure. These are merely examples, and are not intended to be limiting. Drawings are not drawn to scale. Elements with the same reference numerals refer to the same element, and are presumed to have the same material composition and the same thickness range unless expressly indicated otherwise. All features of an original embodiment are presumed to be present in any derived embodiment unless expressly disclosed otherwise. Thus, features described with reference to related embodiments in the drawings and/or in the specification provide support for features in an embodiment. Embodiments are expressly contemplated in which multiple instances of any described element are repeated unless expressly stated otherwise. Embodiments are expressly contemplated in which non-essential elements are omitted even if such embodiments are not expressly disclosed but are known in the art.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Unless explicitly stated otherwise, each element having the same reference numeral is presumed to have the same material composition and to have a thickness within a same thickness range.

Various embodiments disclosed herein relate to a method for forming reliable semiconductor packages that are compatible with system-on-integrated-chip (SoIC) technology. In related die saw processes in semiconductor manufacturing, cracks are often generated in redistribution structures and/or molding compounds and may cause corner chipping, which compromises the integrity of semiconductor packages. These problems are often the result of inadequate edge protection for interposer backside redistribution structures and encapsulation frames. Embodiments of the present disclosure provide a metallic crack-stop structure comprising at least one metallic pillar, which may be used to prevent cracking inside an interposer and to enhance the reliability of a semiconductor package.

According to an aspect of the present disclosure, a composite die including at least one semiconductor die and a molding compound matrix may be provided. A first redistribution structure with first redistribution wiring interconnects formed within first redistribution dielectric layers may be formed over the composite die. A metallic crack-stop structure comprising at least one metallic pillar may be formed over a peripheral region of the first redistribution structure. A connection die may be attached to the center region of the first redistribution structure, and an encapsulation frame may be formed around the connection die and the metallic crack-stop structure. A second redistribution structure may be formed over the connection die, the metallic crack-stop structure, and the encapsulation frame. The second redistribution structure includes second redistribution wiring interconnects formed within second redistribution dielectric layers. An array of metal bump structures may be formed on the second redistribution wiring interconnects. The metallic crack-stop structure may be an electrically inactive structure that remains electrically isolated from the metal bumps.

In some embodiments, the first redistribution structure may include a first edge-seal ring structure that is electrically connected to the metallic crack-stop structure and extends continuously through all of the first redistribution dielectric layers. Similarly, the second redistribution structure may include a second edge-seal ring structure that is electrically connected to the metallic crack-stop structure and extends continuously through all of the second redistribution dielectric layers. The encapsulation frame may be formed by applying a molding compound material around the connection die and the metallic crack-stop structure, followed by a planarization process that exposes top surfaces of the connection die and the metallic crack-stop structure. The connection die may be attached to first bump structure of the first redistribution structure through a solder-mediated bonding. In some embodiments, through-interposer via (TIV) structures may be disposed on second bump structures of the first redistribution structure, and may be formed within the encapsulation frame. The TIV structures may be used to provide electrical connections between the first redistribution wiring interconnects and second redistribution wiring interconnects. A composite package may be provided, which comprises a composite die including at least one semiconductor die and a molding compound die frame, and a composite interposer including a first redistribution structure, a connection die and a metallic crack-stop structure formed within an encapsulation frame, and a second redistribution structure. The metallic crack-stop structure structurally reinforces the encapsulation frame to prevent cracking of the composite interposer. Various aspects of the present disclosure are now described in detail with reference to accompanying figures.

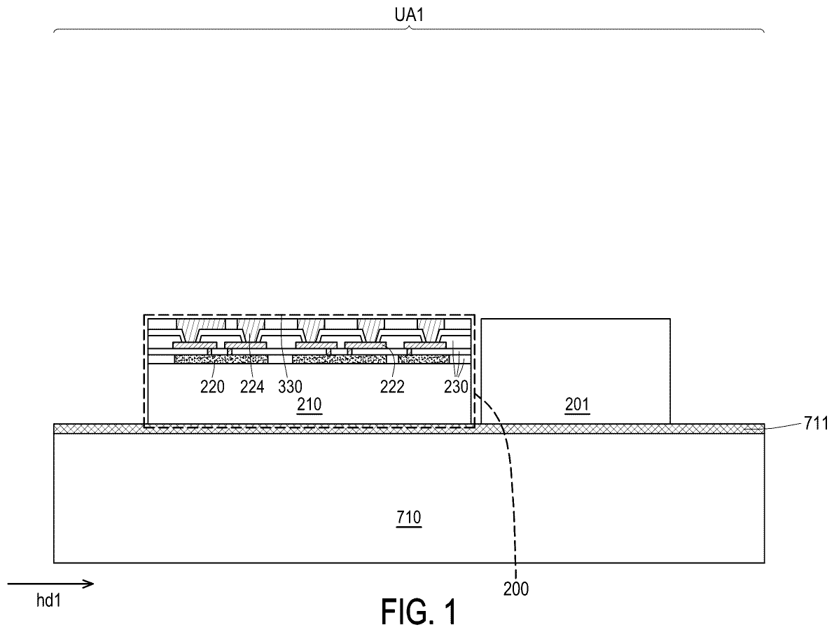

Referring to FIG. 1, an exemplary structure according to an embodiment of the present disclosure is illustrated. The exemplary structure comprises a semiconductor die 200 and an optional dummy die 201 that may be attached to a top side of a first carrier 710. In an embodiment, the first carrier 710 may be a wafer formed of a semiconductor material or a transparent material. For example, the first carrier 710 may be a silicon wafer or a glass wafer. In an embodiment, the first carrier 710 may be a panel formed of a dielectric material or a transparent material. For example, the first carrier 710 may be a glass panel. The first carrier 710 may comprise a two-dimensional array of unit areas UA1 such as a rectangular array of unit areas UA1. In this embodiment, multiple instances of a unit area UA1 may be repeated along a first horizontal direction hd1 with a first pitch, and along a second horizontal direction hd2 with a second pitch. The illustrated portion of the exemplary structure corresponds to a region of a single unit area UA1. Generally, a set of at least one semiconductor die 200 and optionally at least one dummy die 201 may be attached to the first carrier wafer 710 within each unit area UA1. In one embodiment, a die attachment film (DAF) 711 may be applied to the top surface of the first carrier 710, and each set of at least one semiconductor die 200 and optionally at least one dummy die 201 may be attached to the DAF 711 by performing a pick-and-place operation.

Generally, each semiconductor die 200 may be any type of semiconductor die known in the art. For example, each of the at least one semiconductor die 200 in a unit area UA1 may comprise a system-on-chip (SoC) die, a logic die, a memory die, or a semiconductor die of any other type. In one embodiment, a semiconductor die 200 may comprise a die semiconductor substrate 210, which may comprise a single crystalline semiconductor substrate such as a single crystalline semiconductor substrate. Semiconductor devices 220 may be formed on a top surface of the die semiconductor substrate 210. The semiconductor devices 220 may comprise field effect transistors, resistors, diodes, capacitors, inductors, or any other type of semiconductor devices known in the art.

Each semiconductor die 200 may comprise metal interconnect structures 222 formed within dielectric material layers 230 and overlying the semiconductor devices 220. The metal interconnect structures 222 may provide electrical connections among the semiconductor devices 220. Die-side bonding pads 224, i.e., bonding pads that are formed on a semiconductor die 200, may be formed at the topmost level of the dielectric material layers 230. The die-side bonding pads 224 are electrically connected to a semiconductor devices 220 through the metal interconnect structures 222. In one embodiment, the semiconductor die 200 may be attached to the first carrier 710 such that the die semiconductor substrate 210 is more proximal to the first carrier 710 than the die-side bonding pads 224 are to the first carrier 710. Planar horizontal surfaces of the die-side bonding pads 224 may be physically exposed after each semiconductor die 200 is attached to the first carrier 710.

While the present disclosure is described using an embodiment in which a single semiconductor die 200 and a dummy die 201 are attached to the first carrier 710 within each unit area UA1, embodiments are expressly contemplated herein in which two or more semiconductor dies 200 are attached to the first carrier 710. Further embodiments are expressly contemplated herein in which the dummy die 201 is not used, or a plurality of dummy dies 201 is attached to the first carrier wafer 710 in each unit area UA1.

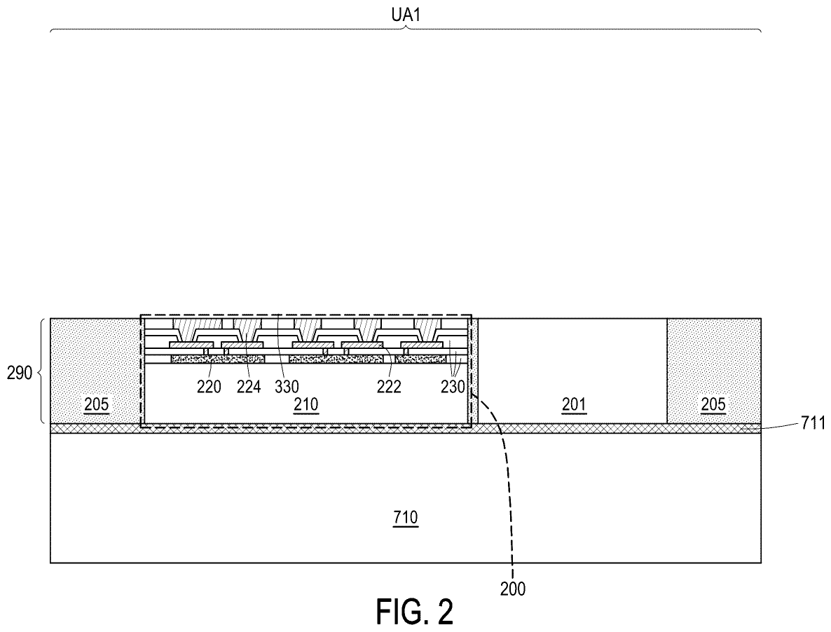

Referring to FIG. 2, an encapsulant, such as a molding compound (MC) material, may be applied to the gaps between neighboring pairs of dies (200, 201) attached to the first carrier 710. The MC material may include an epoxy-containing compound that may be hardened (i.e., cured) to provide a dielectric material portion having sufficient stiffness and mechanical strength. The MC material may include epoxy resin, hardener, silica (as a filler material), and other additives. The MC material may be provided in a liquid form or in a solid form depending on the viscosity and flowability. Liquid MC materials typically provide better handling, good flowability, less voids, better fill, and less flow marks. Solid MC materials typically provide less cure shrinkage, better stand-off, and less die drift. A high filler content (such as 85% in weight) within an MC material may shorten the time in mold, lower the mold shrinkage, and reduce the mold warpage. Uniform filler size distribution in the MC material may reduce flow marks, and may enhance flowability.

The MC material may be cured at a curing temperature to form an MC matrix, which is herein referred to as a first MC matrix or a die-level MC matrix. The die-level MC matrix may be a continuous material layer that extends across the entirety of the first carrier 710. Each portion of the die-level MC matrix located within a unit area UA1 constitutes a first molding compound frame, which is herein referred to as a molding compound die frame 205, or an MC die frame 205. Each MC die frame 205 laterally surrounds a set of at least one semiconductor die 200 and optionally at least one dummy die 201. A planarization process may be performed to remove portions of the MC material that overlies the horizontal plane including the topmost surfaces of the semiconductor dies 200. The top surfaces of the semiconductor dies 200 and the dummy dies 201 may be coplanar with the top surface of the die-level MC matrix. The combination of the semiconductor dies 200, the optional dummy dies 201, and the die-level MC matrix constitutes a reconstituted wafer. The reconstituted wafer may comprise a two-dimensional array of reconstituted dies. Each reconstituted die may be located within a respective unit area UA1, and may comprise at least one semiconductor die 200, optionally at least one dummy die 201, and a molding compound die frame 205.

The illustrated portion of the exemplary structure corresponds to a unit area UA1, i.e., a region including a single repetition unit within the reconstituted wafer. The combination of all material portions located within a unit area UA1 and overlying the die attachment film 711 constitutes a composite die 290. Thus, each composite die 290 comprises at least one semiconductor die 200, at least one optional dummy die 201, and a molding compound die frame 205 (which is a portion of a die-level MC matrix within a unit area UA1).

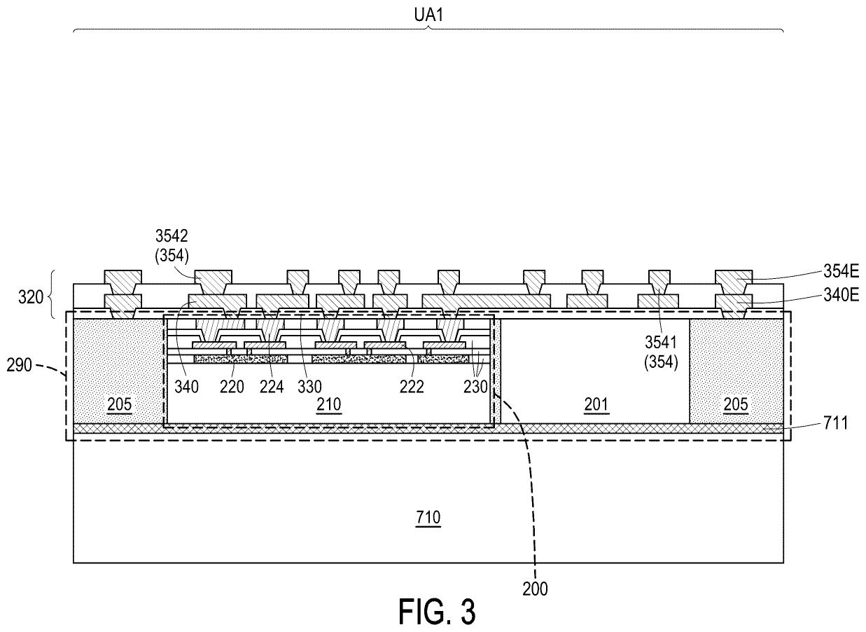

Referring to FIG. 3, first redistribution wiring interconnects 340 formed within first redistribution dielectric layers 330 may be formed over the reconstituted wafer including a two-dimensional array of composite dies 290. The first redistribution dielectric layers 330 include a respective dielectric polymer material such as polyimide (PI), benzocyclobutene (BCB), or polybenzobisoxazole (PBO). Other suitable dielectric polymer material may also be used. Each first redistribution dielectric layer 330 may be formed by spin coating and drying of the respective dielectric polymer material. The thickness of each first redistribution dielectric layer 330 may be in a range from 2 microns to 40 microns, such as from 4 microns to 20 microns. Each first redistribution dielectric layer 330 may be patterned, for example, by applying and patterning a respective photoresist layer thereabove, and by transferring the pattern in the photoresist layer into the first redistribution dielectric layer 330 using an etch process such as an anisotropic etch process. The photoresist layer may be subsequently removed, for example, by ashing.

Each of the first redistribution wiring interconnects 340 may be formed by depositing a metallic seed layer by sputtering, by applying and patterning a photoresist layer over the metallic seed layer to form a pattern of openings through the photoresist layer, by electroplating a metallic fill material (such as copper, nickel, or a stack of copper and nickel), by removing the photoresist layer (for example, by ashing), and by etching portions of the metallic seed layer located between the electroplated metallic fill material portions. The metallic seed layer may include, for example, a stack of a titanium barrier layer and a copper seed layer. The titanium barrier layer may have thickness in a range from 50 nm to 300 nm, and the copper seed layer may have a thickness in a range from 100 nm to 500 nm. The metallic fill material for the first redistribution wiring interconnects 340 may include copper, nickel, or copper and nickel. The thickness of the metallic fill material that is deposited for each first redistribution wiring interconnects 340 may be in a range from 2 microns to 40 microns, such as from 4 microns to 10 microns, although lesser or greater thicknesses may also be used.

The first redistribution wiring interconnects 340 at the topmost level may have general shapes of metal pads having a maximum lateral dimension in a range from 5 microns to 50 microns, such as from 10 microns to 40 microns, and/or from 15 microns to 30 microns, although lesser and greater maximum lateral dimensions may also be used. The lateral dimensions of bottom ends of via portions of the first redistribution wiring interconnects 340 may be in a range from 2 microns to 10 microns, such as from 3 microns to 8 microns, although lesser and greater lateral dimensions may also be used. The total number of levels of the first redistribution wiring interconnects 340 may be in a range from 1 to 20. The combination of the first redistribution wiring interconnects 340 and the first redistribution dielectric layers 330 within each unit area UA1 constitute a redistribution structure, which is herein referred to as a first redistribution structure 320 that is used to provide formation of fan-out bonding structures.

In one embodiment, the first redistribution structure 320 comprises a wiring-level edge-seal ring structure 340E that laterally encloses the entirety of the first redistribution wiring interconnects 340. The wiring-level edge-seal ring structure 340E may comprise at least one rectangular-frame-shaped structure without any lateral perforation therethrough. As used herein, a rectangular-frame-shaped structure refers to a structure that laterally encloses a volume having a horizonal cross-sectional shape of a rectangle in a plan view. Thus, a portion of the first redistribution dielectric layers 330 located inside a wiring-level edge-seal ring structure 340E does not contact, and is laterally spaced from, a portion of the first redistribution dielectric layers 330 located outside the wiring-level edge-seal ring structure 340E. The wiring-level edge-seal ring structure 340E may vertically extend from a bottommost surface of the first redistribution dielectric layers 330 to a topmost surface of the first redistribution dielectric layers 330.

First redistribution bump structures 354 and at least one peripheral bump structure 354E may be formed at the topmost level of the first redistribution structure 320 within each unit area UA1. The first redistribution bump structures 354 and the at least one peripheral bump structure 354E may be formed by deposition and patterning of a metallic bonding material. In one embodiment, the first redistribution bump structures 354 and the at least one peripheral bump structure 354E may comprise copper bump structures that are formed by deposition and patterning of copper. In this embodiment, each top surface of the first redistribution bump structures 354 and the at least one peripheral bump structure 354E may be formed within a same horizontal plane. The height of the copper bump structures may be in a range from 20 microns to 100 microns, although lesser and greater heights may also be used.

The at least one peripheral bump structure 354E may be formed directly on a top surface of the wiring-level edge-seal ring structure 340E. Each peripheral bump structure 354E may comprise a respective rectangular-frame-shaped structure without any lateral perforation therethrough. The combination of the wiring-level edge-seal ring structure 340E and the peripheral bump structure 354E constitutes a first edge-seal ring structure (340E, 354E) The first edge-seal ring structure (340E, 354E) continuously extends in the peripheral region of the first redistribution structure 320 to provide at least one lateral enclosure structure, which may comprise a plurality of nested enclosure structures. The first edge-seal ring structure (340E, 354E) vertically extends from a bottommost one of the first redistribution dielectric layers 330 to a topmost one of the first redistribution dielectric layers 330. The lateral extent of the first edge-seal ring structure (340E, 354E) along a radial direction (i.e., a lateral direction that is perpendicular to a most proximal edge of the unit area UA1) may be in a range from 3 microns to 30 microns, such as from 6 microns to 20 microns, although lesser and greater lateral dimensions may also be employed.

The first redistribution bump structures 354 are subsequently used to attach structural elements thereupon. In one embodiment, the first redistribution bump structures 354 may comprise first bump structures 3541 located in a center region and configured for bonding with a semiconductor die, and second bump structures 3542 configured for mating with through-interposer via (TIV) structures to be subsequently disposed thereupon, laterally offset from the first bump structures 3541, and located inside an area enclosed by the at least one peripheral bump structure 354E. The first bump structures 3541 may be configured for bonding with a semiconductor die. The second bump structures 3542 may be configured for mating with through-interposer via (TIV) structures to be subsequently disposed thereupon. Thus, each top surface of the at least one peripheral bump structure 354E, the first bump structures 3541, and the second bump structures 3542 may be formed within a same horizontal plane.

In one embodiment, each first bump structure 3541 may have a lateral dimension or a diameter in a range from 2 microns to 20 microns, such as from 4 microns to 10 microns, although lesser and greater diameters may also be used. In one embodiment, each second bump structure 3542 may have a lateral dimension or a diameter in a range from 10 microns to 100 microns, such as from 20 microns to 60 microns, although lesser and greater diameters may also be used. Each peripheral bump structure 354E may have a width (as measured between an inner sidewall and an outer sidewall) in a range from 10 microns to 200 microns, such as from 20 microns to 100 microns, although lesser and greater widths may also be used.

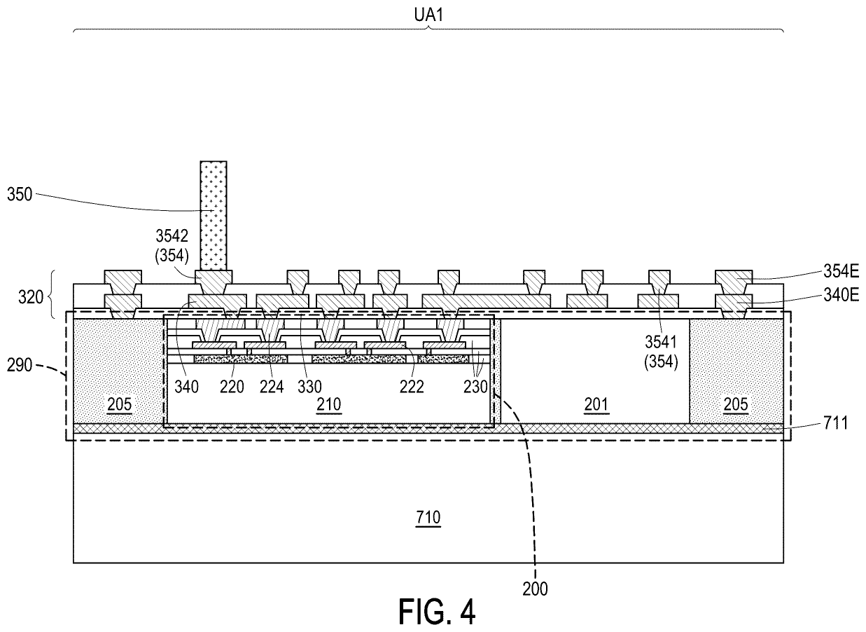

Referring to FIG. 4, through-interposer via (TIV) structures 350 may be disposed on the second bump structures 3542. In this embodiment, the second bump structures 3542 may have suitable lateral dimensions (such as dimensions in a range from 10 microns to 60 microns) for accommodating the TIV structures 350. Each TIV structure 350 may have a shape of a circular or elliptical cylinder. The diameter of a maximum lateral dimension of each TIV structure 350 may be in a range from 10 microns to 100 microns, although lesser and greater dimensions may also be used. The height of the TIV structures 350 may be in a range from 30 microns to 300 microns, although lesser and greater heights may also be used. In one embodiment, the TIV structures 350 are electrically connected to a respective one of the first redistribution wiring interconnects 340 upon disposition on the second bump structures 3542.

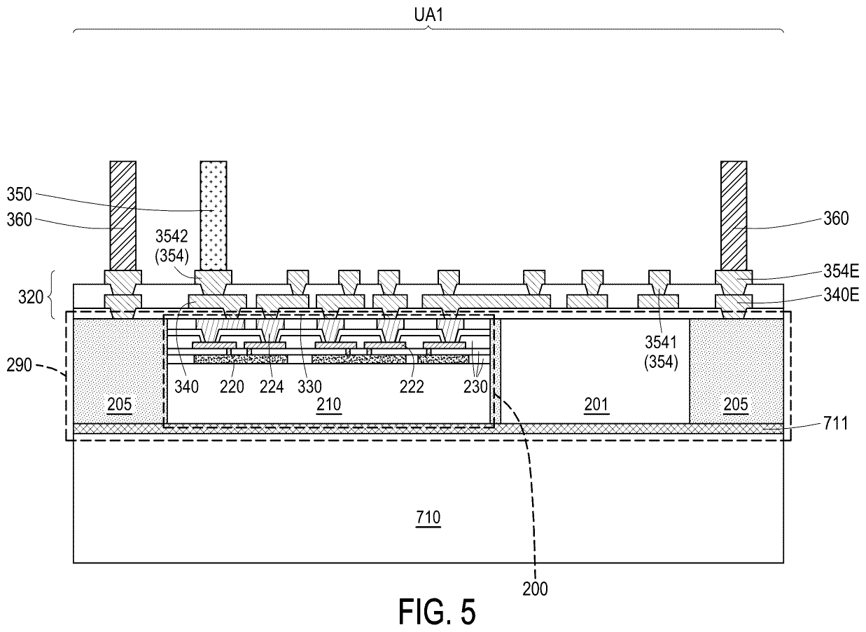

Referring to FIG. 5, a metallic crack-stop structure 360 may be disposed on the first redistribution structure 320. Specifically, the metallic crack-stop structure 360 may be disposed directly on the top surface(s) of the at least one peripheral bump structure 354E. The metallic crack-stop structure 360 comprises at least one metallic pillar. The metallic crack-stop structure 360 may have the same height as the TIV structures 350. The metallic crack-stop structure 360 may comprise, and/or may consist essentially of, a transition metal such as W, Ta, Mo, Nb, Co, Ru, Cu, etc. The metallic crack-stop structure 360 may comprise a single metallic pillar or a plurality of metallic pillars. The lateral dimension of each metallic pillar along a radial direction (i.e., any horizontal direction radiating outward from a geometrical center of the first redistribution structure 320) may be in a range from 10 microns to 200 microns, such as from 20 microns to 100 microns, although lesser and greater lateral dimensions may also be used.

In one embodiment, the metallic crack-stop structure 360 may comprise at least one rectangular-frame-shaped structure that continuously extends over a peripheral region of the first redistribution structure 320 on the top surface(s) of the at least one peripheral bump structure 354E. Each rectangular-frame-shaped structure may be free of any lateral opening therethrough, and may laterally enclose a respective enclosed volume. In one embodiment, each rectangular-frame-shaped structure may have a shape of a respective rectangular frame, i.e., a frame having a set of inner sidewalls located on sides of an inner rectangle in a plan view and having a set of outer sidewalls located on sides of an outer rectangle in the plan view.

Alternatively or additionally, the metallic crack-stop structure 360 may comprise at least one set of discrete metallic pillar structures that are laterally spaced from one another and arranged along over the peripheral region of the first redistribution structure 320 on the top surface(s) of the at least one peripheral bump structure 354E. In this embodiment, each peripheral bump structure 354E may have a respective frame shape (such as a respective rectangular frame shape), and each set of metallic pillar structures may be disposed on the top surface of a respective one of the peripheral bump structures 354E in a manner that generally encloses an area that is also enclosed by the respective peripheral bump structure 354E. Each metallic pillar structure may have a shape a respective cylinder. The horizonal cross-sectional shape of each cylinder may be a circle, an oval, a rectangle, a rounded rectangle, or an L-shaped area, etc.

Generally, a metallic crack-stop structure 360 comprising at least one metallic pillar may be disposed over a peripheral region of the first redistribution structure 320. In one embodiment, the metallic crack-stop structure 360 may directly contact, and may be electrically connected to, the first edge-seal ring structure (340E, 354E). The lateral extent of the metallic crack-stop structure 360 along a radial direction (i.e., a lateral direction that is perpendicular to a most proximal edge of the unit area UA1) may be in a range from 3 microns to 30 microns, such as from 6 microns to 20 microns, although lesser and greater lateral dimensions may also be employed.

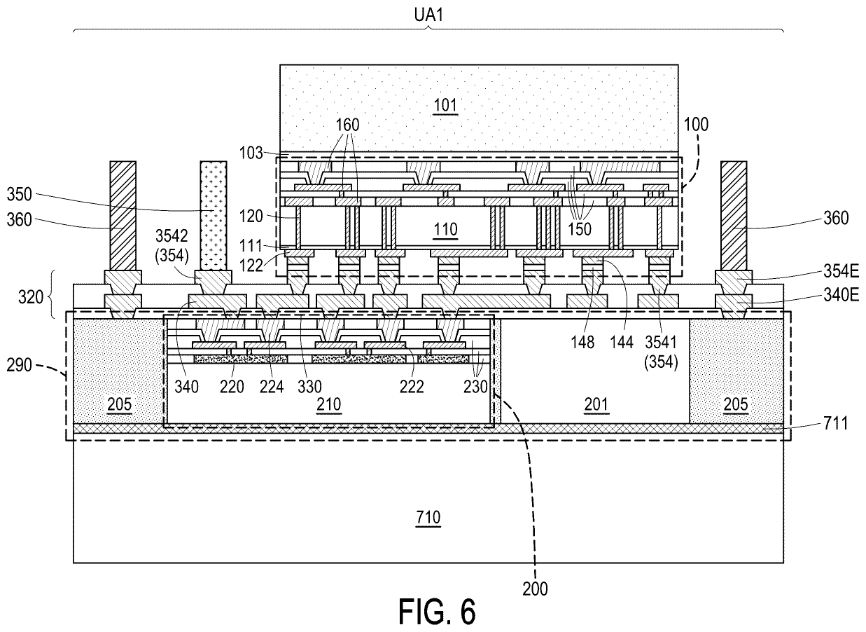

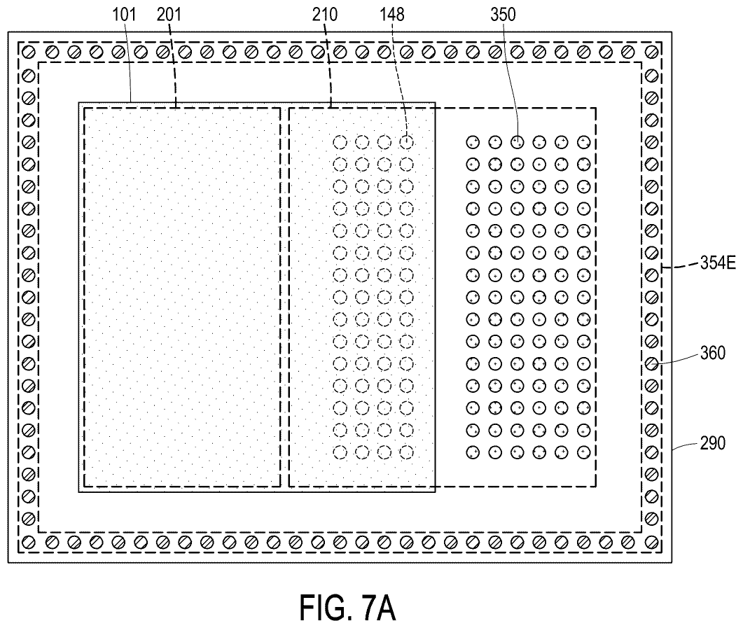

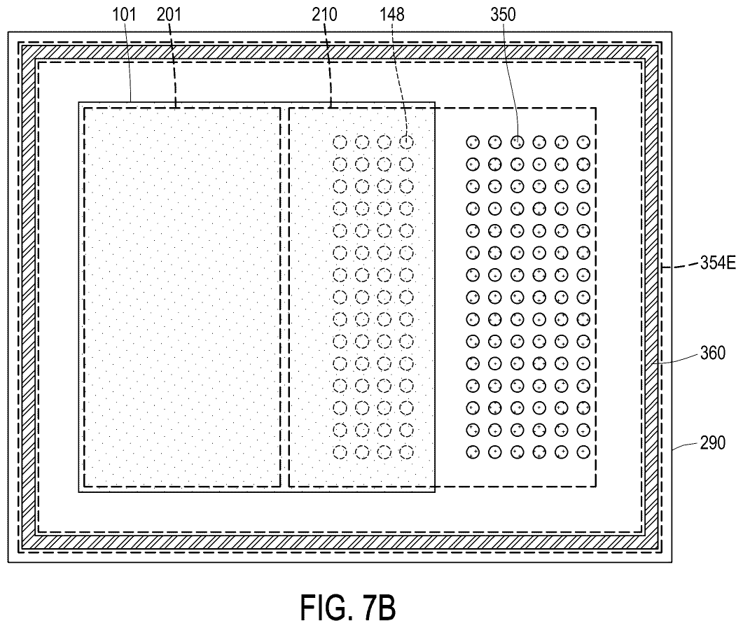

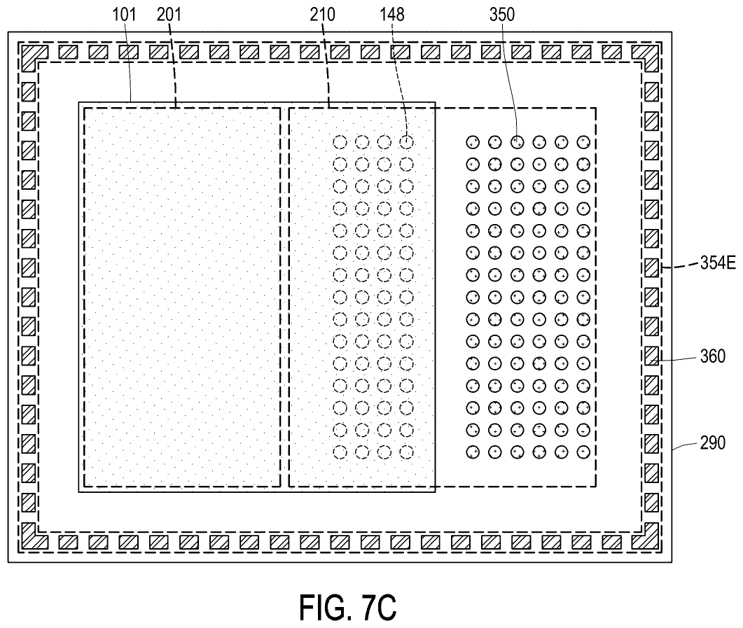

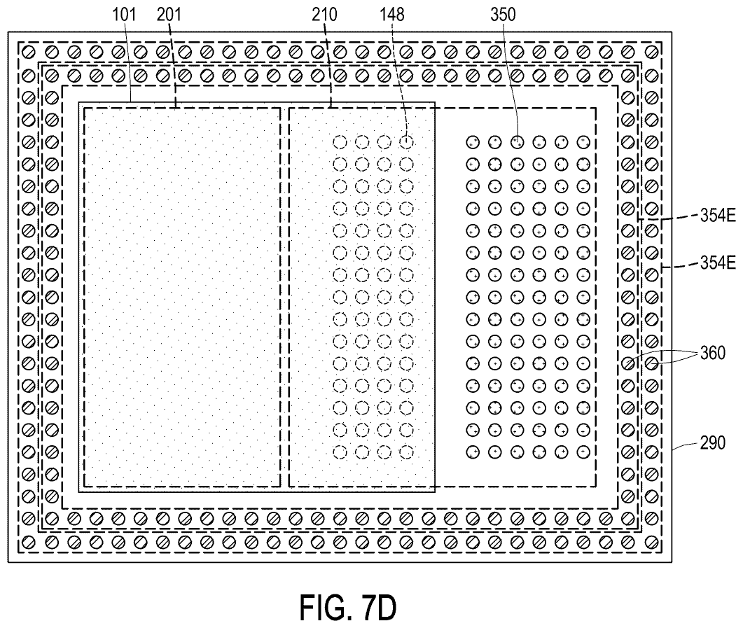

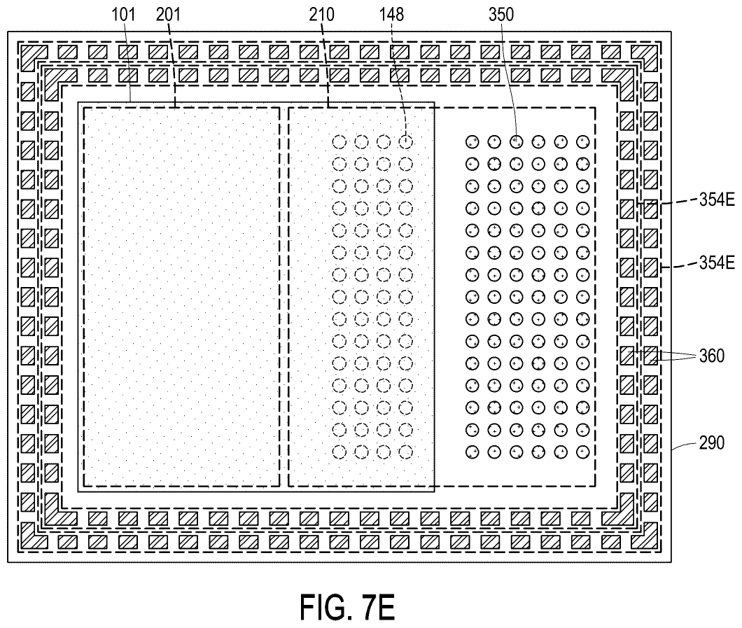

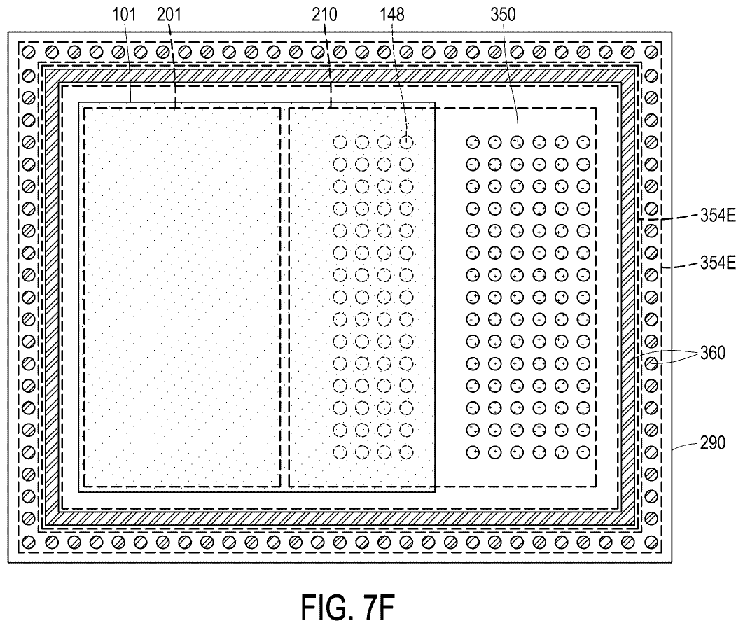

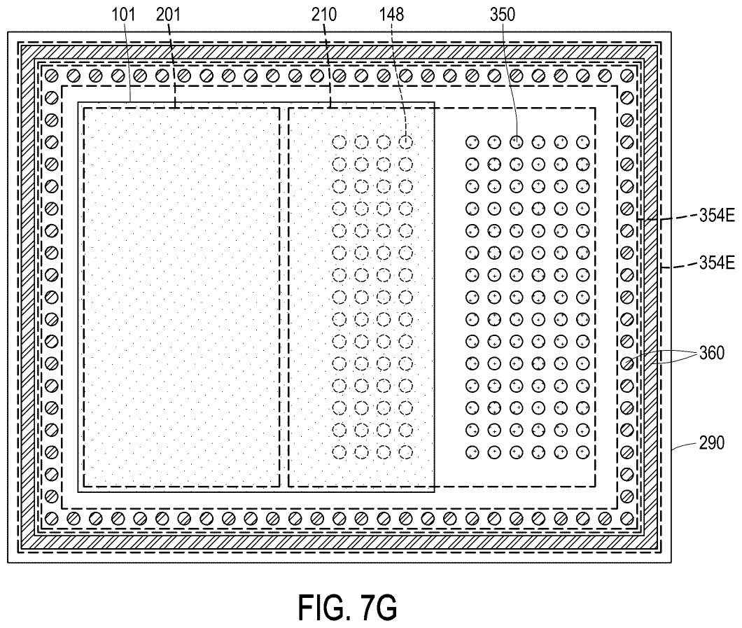

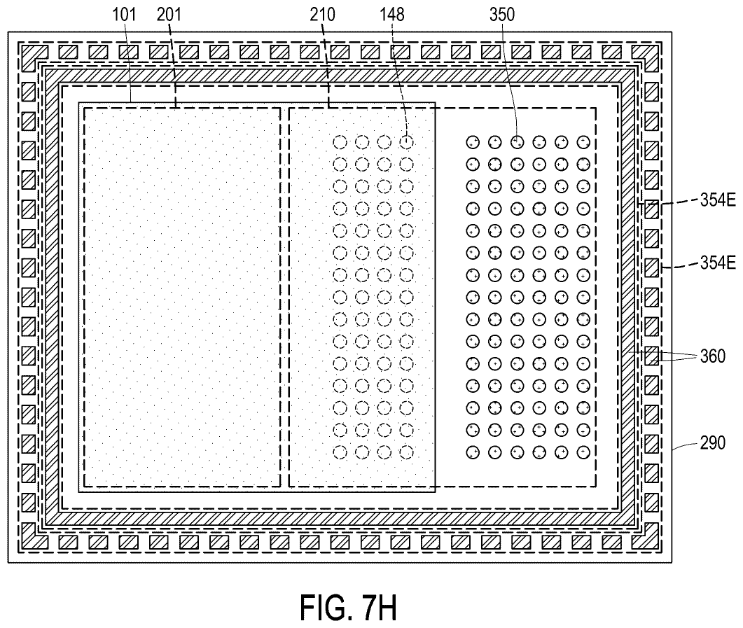

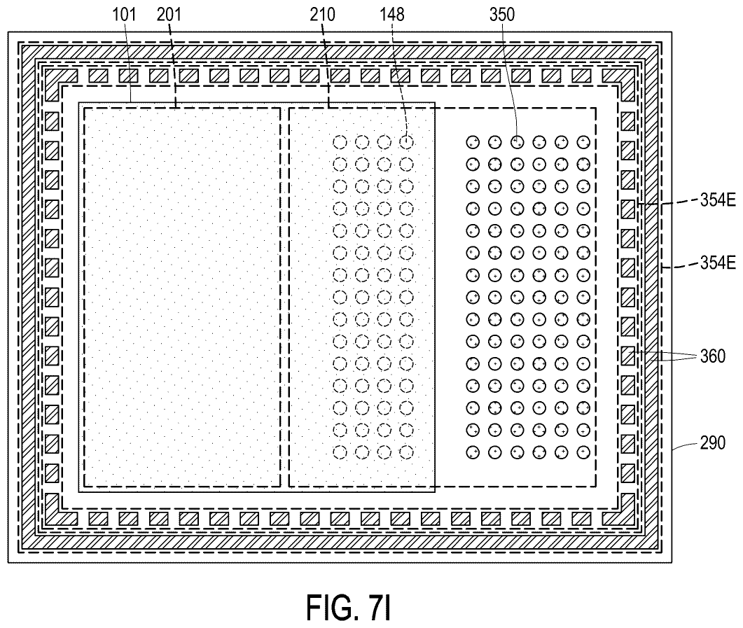

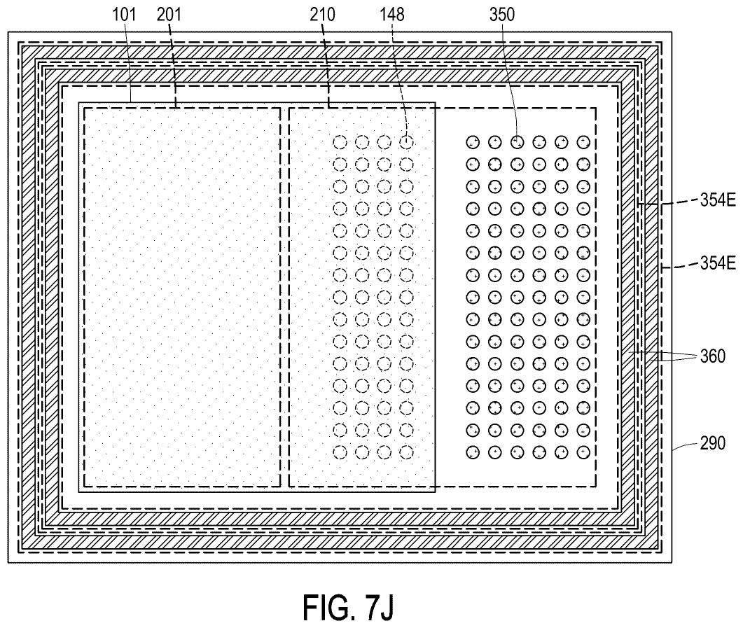

Referring to FIGS. 6 and 7A-7J, a connection die 100 may be attached to the center region of the first redistribution structure 320 within each unit area UA1. In one embodiment, the connection die 100 may comprise a through-substrate-via-containing die, i.e., a TSV-containing die. As used herein, a “through-substrate-via-containing die” or a “TSV-containing die” refers to a die that includes through substrate vias that vertically extend through a substrate. The substrate through which the through substrate vias vertically extend is herein referred to as a “TSV substrate.” The connection die 100 may comprise through-substrate via (TSV) structures 120 formed within a TSV substrate 110, connection-die redistribution dielectric layers 150 located on a first side of the TSV substrate 110, connection-die redistribution wiring interconnects 160 that are formed within the connection-die redistribution dielectric layers 150, an optional dielectric capping layer 111 located on a second side of the TSV substrate 110, metal pads 122 contacting end surfaces of the through-substrate via structures 120 and contacting the optional dielectric capping layer 111 (if present), and connection-die bump structures 144 that are located on the metal pads and having a mirror image pattern of the pattern of the first bump structures 3541. In one embodiment, the TSV substrate 110 may comprise a semiconductor substrate such as silicon substrate and having a thickness in a range from 5 microns to 20 microns. Tubular insulating spacers (not illustrated) may be provided around each through-substrate via structure 120. In one embodiment, the connection die 100 may be temporarily structurally supported by a temporary support substrate 101, which may be bonded to a distal side of the connection die 100 through an adhesive layer 103. The distal side of the connection die 100 refers to the opposite side of the connection die 100 that contains the connection-die bump structures 144.

In an illustrative example, a two-dimensional array of connection dies 100 may be formed on a support wafer (such as a silicon wafer). In this embodiment, a continuous adhesive layer having a same material composition and a same thickness as the adhesive layer 103 may be formed over the support wafer. The two-dimensional array of connection dies 100 may be formed over the continuous adhesive layer such that the arrays of connection-die bump structures 144 are formed on top. Solder material portions 148 may be attached to the connection-die bump structures 144. The support wafer may be optionally thinned from the backside, for example, by grinding. The support wafer and the two-dimensional array of connection dies 100 may be diced along dicing channels to provide assemblies of a connection die 100 and a temporary support substrate 101. Each temporary support substrate 101 is a diced portion of the support wafer. An assembly of a connection die 100 and a temporary support substrate 101 may be bonded to an array of first bump structures 3541 by a solder-mediated bonding, i.e., by reflowing and resolidifying the solder material portions 148.

Generally, a connection die 100 is attached to a center region of the first redistribution structure 320. In one embodiment, the first redistribution structure 320 comprises first bump structures 3541 in the center region, the connection die 100 comprises connection-die bump structures 144, and the connection die 100 is attached to the first redistribution structure 320 through a solder-mediated bonding between the connection-die bump structures 144 and the first bump structures 3541, i.e., via an array of solder material portions 148. In one embodiment, the first bump structures 3541 may comprise copper pillars configured for chip connection (C2) bonding, and the connection-die bump structures 144 may comprise additional copper pillars configured for chip connection bonding. In other words, the first bump structures 3541 and the connection-die bump structures 144 may comprise microbump structures.

In one embodiment, the heights of the metallic crack-stop structure 360 and the TIV structures 350 may be selected such that top surfaces of the metallic crack-stop structure 360 and the TIV structures 350 are located at, or about, the horizontal plane including the top surface of the connection die 100. The lateral extent of each metallic crack-stop structure 360 along a radial direction (i.e., a lateral direction that is perpendicular to a most proximal edge of the unit area UA1) may be in a range from 3 microns to 30 microns, such as from 6 microns to 20 microns, although lesser and greater lateral dimensions may also be employed.

As discussed above, the metallic crack-stop structure 360 may be formed in various configurations. For example, the metallic crack-stop structure 360 may comprise at least one rectangular-frame-shaped structure that continuously extends over a peripheral region of the first redistribution structure 320 on the top surface(s) of the at least one peripheral bump structure 354E and/or at least one set of discrete metallic pillar structures that are laterally spaced from one another and arranged along over the peripheral region of the first redistribution structure 320 on the top surface(s) of the at least one peripheral bump structure 354E. FIGS. 7A-7J are top down views of various configurations of the exemplary structure after the processing steps of FIG. 6.

FIG. 7A illustrates a first exemplary configuration for the metallic crack-stop structure 360, in which the metallic crack-stop structure 360 comprises a plurality of metallic pillars that are laterally spaced from one another and arranged along a peripheral region of the first redistribution structure 320. The connection die 100 has an areal overlap with the semiconductor die 200, and may, or may not, have an areal overlap with the dummy die 201. In one embodiment, each of the metallic pillars may have a respective horizontal cross-sectional shape of a circle, an ellipse, a rectangle, or a rounded rectangle. Sidewalls of the temporary support substrate 101 may be vertically coincident with sidewalls of the connection die 100. the connection die 100 is laterally enclosed by the metallic crack-stop structure 360 upon attachment to the center region of the first redistribution structure 320.

FIG. 7B illustrates a second exemplary configuration for the metallic crack-stop structure 360, in which the metallic crack-stop structure 360 comprises a rectangular metallic frame that overlies the peripheral region of the first redistribution structure 320. The second exemplary configuration may be derived from the first exemplary configuration by using a single rectangular frame for the metallic crack-stop structure 360 instead of the plurality of metallic pillars that are laterally spaced from one another.

FIG. 7C illustrates a third exemplary configuration for the metallic crack-stop structure 360, in which the metallic crack-stop structure 360 comprises a plurality of metallic pillars that are laterally spaced from one another and arranged along a peripheral region of the first redistribution structure 320. The third exemplary configuration may be derived from the first exemplary configuration by changing horizontal cross-sectional shapes of the metallic pillars into rectangular shapes or L-shapes. Alternatively, the third exemplary configuration may be derived from the second exemplary structure by dividing the rectangular frame illustrated in FIG. 7B into multiple pieces such that each divided portions of the rectangular frame becomes a respective metallic pillar.

FIG. 7D illustrates a fourth exemplary configuration for the metallic crack-stop structure 360, which may be derived from the first exemplary configuration by using multiple frame-shaped arrangements of metallic pillars. Each frame-shaped arrangement of metallic pillars comprises a respective set of metallic pillars that are laterally spaced from one another and arranged along a peripheral region of the first redistribution structure 320 and overlying, and contacting, a respective frame-shaped structure of a plurality of peripheral bump structure 354E. The frame-shaped arrangements of the metallic pillars may be nested among one another.

FIG. 7E illustrates a fifth exemplary configuration for the metallic crack-stop structure 360, which may be derived from the third exemplary configuration by using multiple frame-shaped arrangements of metallic pillars. Each frame-shaped arrangement of metallic pillars comprises a respective set of metallic pillars that are laterally spaced from one another and arranged along a peripheral region of the first redistribution structure 320 and overlying, and contacting, a respective frame-shaped structure of a plurality of peripheral bump structure 354E. The frame-shaped arrangements of the metallic pillars may be nested among one another.

FIG. 7F illustrates a sixth exemplary configuration for the metallic crack-stop structure 360, which may be derived from the first exemplary configuration and the second configuration by using a frame-shaped arrangement of metallic pillars illustrated in FIG. 7A and a rectangular metallic frame illustrated in FIG. 7B. The frame-shaped arrangement of metallic pillars comprises a set of metallic pillars that are laterally spaced from one another and arranged along a peripheral region of the first redistribution structure 320 and overlying, and contacting, a frame-shaped structure of a plurality of peripheral bump structure 354E. The frame-shaped arrangement of the metallic pillars and the rectangular metallic frame may be nested. In the illustrated example, the frame-shaped arrangement encircles the rectangular metallic frame.

FIG. 7G illustrates a seventh exemplary configuration for the metallic crack-stop structure 360, which may be derived from the first exemplary configuration and the second configuration by using a frame-shaped arrangement of metallic pillars illustrated in FIG. 7A and a rectangular metallic frame illustrated in FIG. 7B. The frame-shaped arrangement of metallic pillars comprises a set of metallic pillars that are laterally spaced from one another and arranged along a peripheral region of the first redistribution structure 320 and overlying, and contacting, a frame-shaped structure of a plurality of peripheral bump structure 354E. The frame-shaped arrangement of the metallic pillars and the rectangular metallic frame may be nested. In the illustrated example, the rectangular metallic frame encircles the frame-shaped arrangement.

FIG. 7H illustrates an eighth exemplary configuration for the metallic crack-stop structure 360, which may be derived from the second exemplary configuration and the third configuration by using a frame-shaped arrangement of metallic pillars illustrated in FIG. 7C and a rectangular metallic frame illustrated in FIG. 7B. The frame-shaped arrangement of metallic pillars comprises a set of metallic pillars that are laterally spaced from one another and arranged along a peripheral region of the first redistribution structure 320 and overlying, and contacting, a frame-shaped structure of a plurality of peripheral bump structure 354E. The frame-shaped arrangement of the metallic pillars and the rectangular metallic frame may be nested. In the illustrated example, the frame-shaped arrangement encircles the rectangular metallic frame.

FIG. 7I illustrates a ninth exemplary configuration for the metallic crack-stop structure 360, which may be derived from the second exemplary configuration and the third configuration by using a frame-shaped arrangement of metallic pillars illustrated in FIG. 7C and a rectangular metallic frame illustrated in FIG. 7B. The frame-shaped arrangement of metallic pillars comprises a set of metallic pillars that are laterally spaced from one another and arranged along a peripheral region of the first redistribution structure 320 and overlying, and contacting, a frame-shaped structure of a plurality of peripheral bump structure 354E. The frame-shaped arrangement of the metallic pillars and the rectangular metallic frame may be nested. In the illustrated example, the rectangular metallic frame encircles the frame-shaped arrangement.

FIG. 7J illustrates a tenth exemplary configuration for the metallic crack-stop structure 360, which may be derived from the second exemplary configuration by using multiple rectangular metallic frames as multiple metallic pillars. The rectangular metallic frames may be nested among one another.

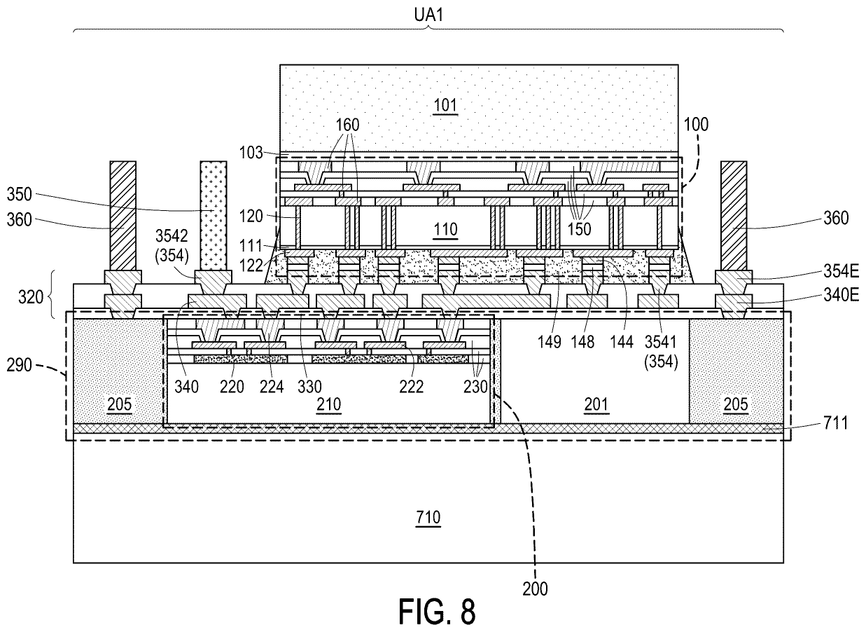

Referring to FIG. 8, an underfill material may be applied to the gap between the connection die 100 and the first redistribution structure 320 to form an underfill material portion 149.

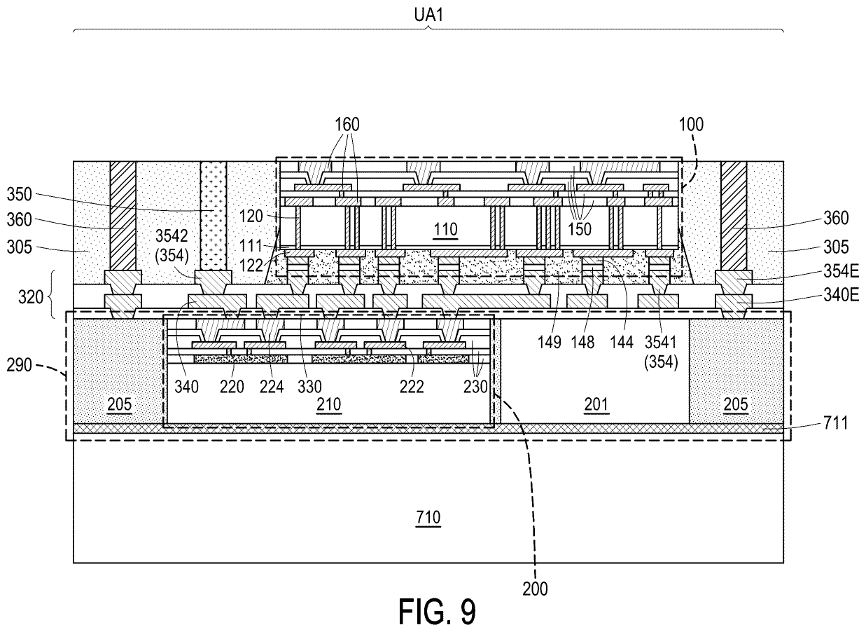

Referring to FIG. 9, the adhesive layer 103 may be decomposed, for example, by applying heat. In one embodiment, the exemplary structure may be annealed above the decomposition temperature of the material of the adhesive layer 103, which may be in a range from 200 degrees Celsius to 250 degrees Celsius. The temporary support substrate 101 is detached from the connection die 100 within each unit area UA1. A suitable clean process may be performed to remove residual materials from the physically exposed top surface of each connection die 100.

A molding compound material may be applied around a two-dimensional array of connection dies 100, a two-dimensional array of metallic crack-stop structures 360, and a two-dimensional array of clusters of TIV structures 350. The molding compound material is applied around each connection die 100, each TIV structure 350, and each metallic crack-stop structure 360. A planarization process may be performed to remove the portion of the molding compound material from above a planarization horizontal plane. The planarization horizontal plane refers to a horizontal plane above which materials of the connection dies 100, the TIV structures 350, and the metallic crack-stop structures 360 are removed, for example, by chemical mechanical polishing. The planarization horizontal plane may be located at, or below, the lowest horizontal plane among the horizontal planes that include top surfaces of the connection dies 100, top surfaces of the TIV structures 350, or top surfaces of the metallic crack-stop structures 360. In one embodiment, the top surfaces of the connection dies 100, the top surfaces of the TIV structures 350, and the top surfaces of the metallic crack-stop structures 360 may be formed within a same horizontal plane during the processing steps described with reference to FIGS. 4-7J so that collateral removal of upper portions of the connection dies 100, the TIV structures 350, and the metallic crack-stop structures 360 during the planarization process is minimized.

Top surfaces of the connection dies 100, the TIV structures 350, and the metallic crack-stop structures 360 are physically exposed at the planarization horizontal plane after the planarization process. The remaining portion of the molding compound material comprises a molding compound interposer matrix. Each portion of the molding compound interposer matrix located within a unit area UA1 constitutes an encapsulation frame 305. Each encapsulation frame 305 laterally surrounds a respective connection die 100, a respective cluster of TIV structures 350, and a respective metallic crack-stop structure 360 (which may comprise at least one frame-shaped continuous metallic pillar and/or as at least one frame-shaped arrangements of discrete metallic pillars). The entirety of the top surfaces of the connection dies 100, the TIV structures 350, the metallic crack-stop structures 360, and the encapsulation frames 305 may be formed within a same horizontal plane, i.e., the planarization horizontal plane.

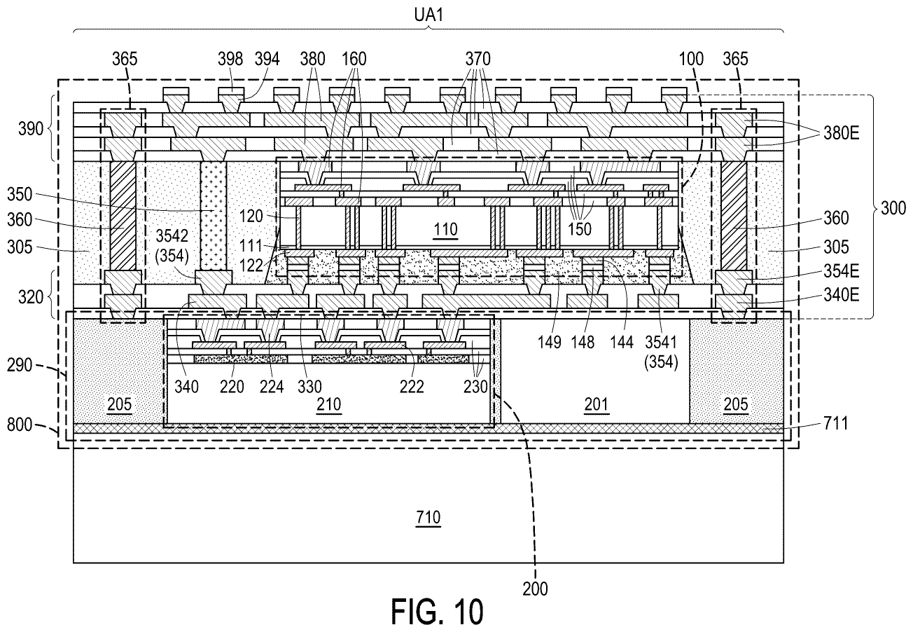

Referring to FIG. 10, a second redistribution structure 390 may be formed over each assembly of a connection die 100, TIV structures 350, a metallic crack-stop structure 360, and an encapsulation frames 305. The second redistribution structure 390 comprises second redistribution wiring interconnects 380 formed within second redistribution dielectric layers 370. Generally, the processing steps described with reference to FIG. 3 may be performed mutatis mutandis to form the second redistribution structure 390. In one embodiment, the TIV structures 350 may be electrically connected to a respective one of the second redistribution wiring interconnects 380 upon formation of the second redistribution wiring interconnects 380.

In one embodiment, the second redistribution structure 390 comprises a second edge-seal ring structure 380E that laterally encloses the entirety of the second redistribution wiring interconnects 380. The second edge-seal ring structure 380E may comprise at least one rectangular-frame-shaped structure without any lateral perforation therethrough. Thus, a portion of the second redistribution dielectric layers 370 located inside a second edge-seal ring structure 380E does not contact, and is laterally spaced from, a portion of the second redistribution dielectric layers 370 located outside the second edge-seal ring structure 380E. The second edge-seal ring structure 380E may vertically extend from a bottommost surface of the second redistribution dielectric layers 370 to a topmost surface of the second redistribution dielectric layers 370. The lateral extent of the second edge-seal ring structure 380E along a radial direction (i.e., a lateral direction that is perpendicular to a most proximal edge of the unit area UA1) may be in a range from 3 microns to 30 microns, such as from 6 microns to 20 microns, although lesser and greater lateral dimensions may also be employed. The combination of the first edge-seal ring structure (340E, 354E), metallic crack-stop structure 360, and the second edge-seal ring structure 380E constitutes an interposer edge protection assembly 365 composed of metallic structures and continuously extending around the periphery of the interposer 300 to provide mechanical support to the peripheral region of the interposer 300. The metallic crack-stop structures 360 may, or may not, have lateral openings therethrough depending on the configuration of the metallic crack-stop structures 360, i.e., depending on whether the metallic crack-stop structure 360 is formed as a single contiguous metallic pillar having a tubular configuration or as multiple metallic pillars that are laterally spaced among one another.

Second redistribution bump structures 394 may be formed at the topmost level of the second redistribution structure 390 within each unit area UA1. The second redistribution bump structures 394 may be formed by deposition and patterning of a metallic bonding material. In one embodiment, the second redistribution bump structures 394 may comprise copper bump structures that are formed by deposition and patterning of copper. The second redistribution bump structures 394 may be formed as microbump structures configured for chip connection (C2) bonding, or as metallic bonding pads configured for controlled-collapse chip connection (C4) bonding. Solder material portions 398 may be attached to the second redistribution bump structures 394.

Each combination of a first redistribution structure 320, a connection die 100, TIV structures 350, a metallic crack-stop structure 360, an encapsulation frame 305, a second redistribution structure 390, and ancillary structures (such as solder material portions 148 and an underfill material portion 149) located within a unit area UA1 constitutes an interposer 300. Each contiguous combination of a composite die 290 and an interposer 300 constitutes a composite package 800, which is a bonded assembly including at least one semiconductor die 200 and an interposer 300. Each set of second redistribution bump structures 394 located in an interposer 300 is subsequently used to attach the interposer 300 to another structure. As such, the second redistribution bump structures 394 are also referred to as on-interposer metal bump structures 394.

Generally speaking, the second redistribution structure 390 includes second redistribution wiring interconnects 380 formed within second redistribution dielectric layers 370, and is located over the connection die 100, the metallic crack-stop structure 360, and the encapsulation frame 305. An array of metal bump structures (such as on-interposer metal bump structures 394) may be formed on the second redistribution wiring interconnects 380. The metallic crack-stop structure 360 is not an electrically active component, and thus, may be electrically isolated from the array of metal bump structures (such as on-interposer metal bump structures 394). In one embodiment, the second redistribution structure 390 comprises a second edge-seal ring structure 380E that continuously extends along a peripheral region of the second redistribution structure 390 and vertically extends from a bottommost one of the second redistribution dielectric layers 370 to a topmost one of the second redistribution dielectric layers 370. In one embodiment, the metallic crack-stop structure 360 may contact, and may be electrically connected to, the second edge-seal ring structure 380E.

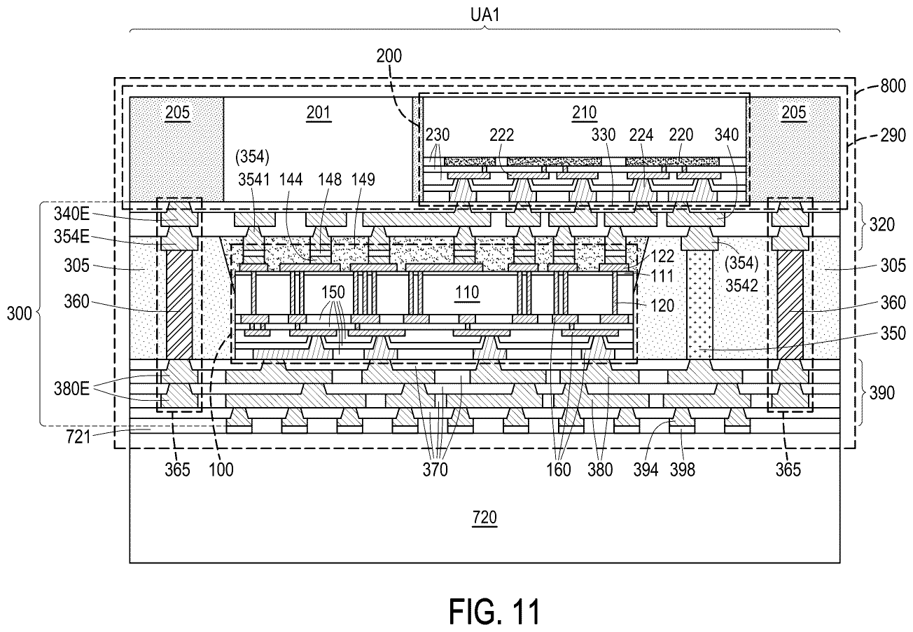

Referring to FIG. 11, an adhesive layer 721 may be applied over the on-interposer metal bump structures 394 and solder material portions 398. A second carrier wafer 720 may be attached to a reconstituted wafer including a stack of a two-dimensional array of composite dies 290 and a two-dimensional array of interposers 300 through the adhesive layer 721. The first carrier wafer 710 may be detached from the reconstituted wafer by inducing decomposition of the die attachment film 711. The physically exposed backside surface of the composite dies 290 may be thinned, for example, by grinding or polishing. A suitable cleaning process may be performed on the backside surface of the composite dies 290 after thinning the composite dies 290.

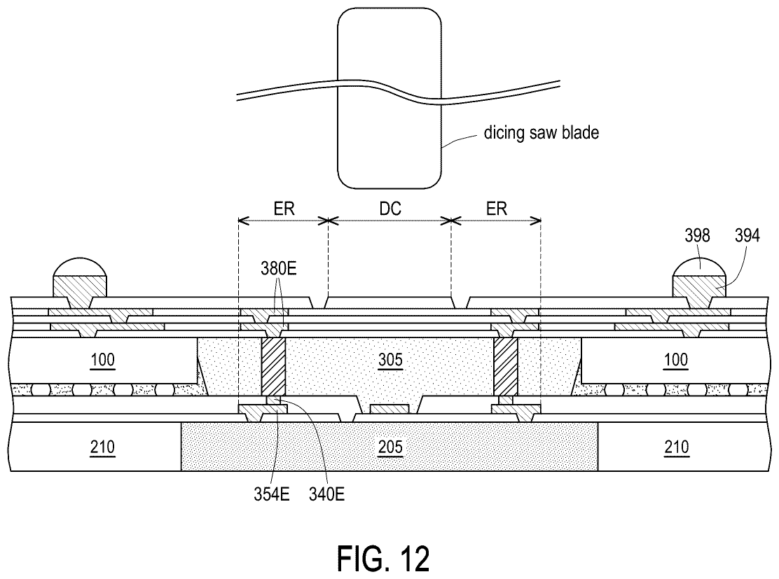

Referring to FIG. 12, the adhesive layer 721 may be decomposed, for example, by applying heat. In one embodiment, the exemplary structure may be annealed above the decomposition temperature of the material of the adhesive layer 721, which may be in a range from 200 degrees Celsius to 250 degrees Celsius. The second carrier wafer 720 is detached from the reconstituted wafer including a two-dimensional array of composite packages 800. A suitable clean process may be performed to remove residual materials from the physically exposed top surface of the second redistribution structures 390 and from around the on-interposer metal bump structures 394 and solder material portions 398.

The reconstituted wafer is diced along dicing channels (DC). Generally, the metallic crack-stop structures 360 are positioned alongside the dicing channels (DC) within an edge region (ER) of a respective interposer 300. Thus, each metallic crack-stop structure 360 is located adjacent to a sidewall of a respective composite package 800 upon dicing the reconstituted wafer.

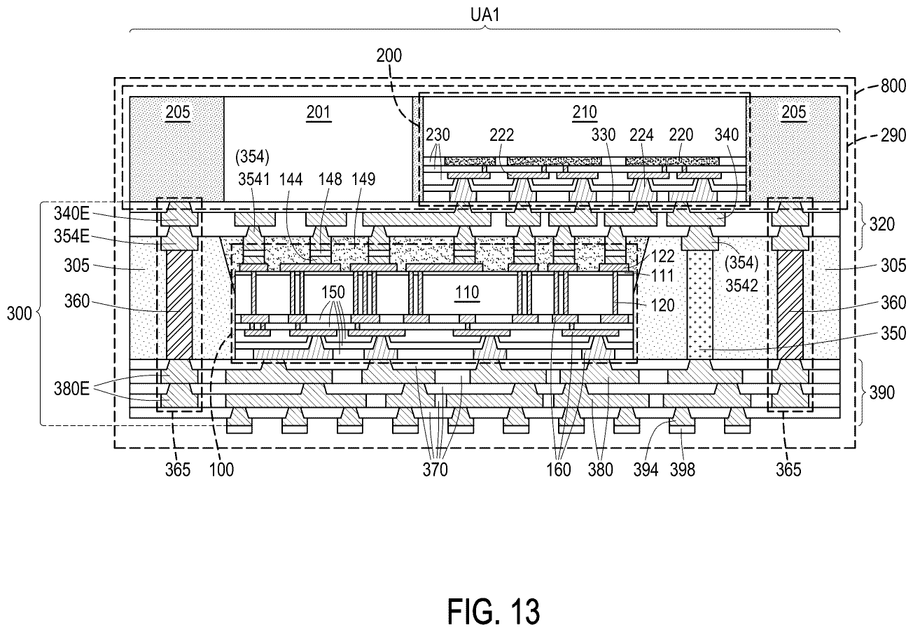

Referring to FIG. 13, a composite package 800 is illustrated after singulation. Physically exposed sidewalls of various components of the composite package 800 may be vertically coincident (i.e., located within a same vertical plane) because all components of the composite package 800 are provided through dicing of the reconstituted wafer.

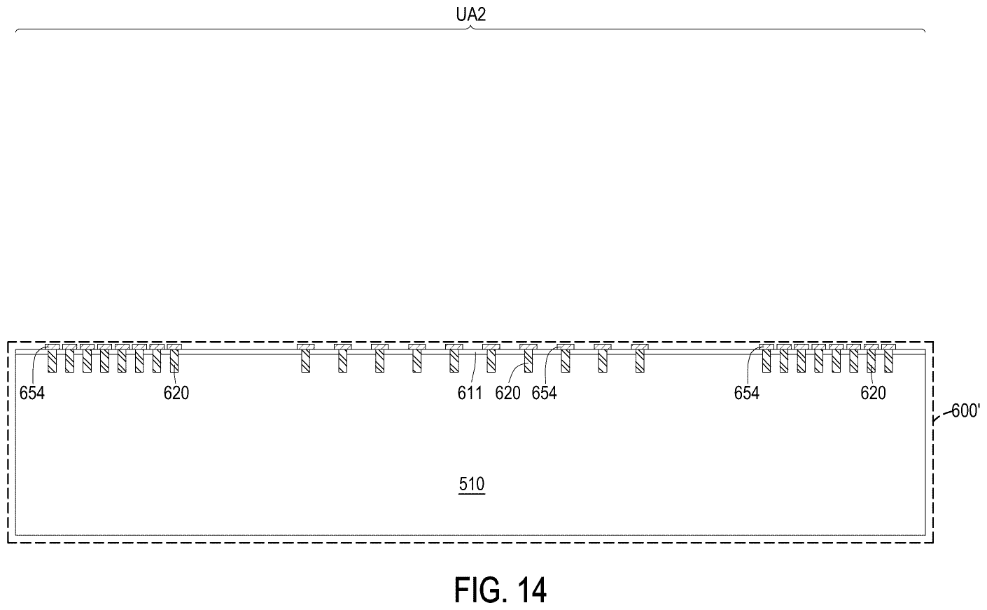

Referring to FIG. 14, an in-process semiconductor interposer 600′ is illustrated, which may be provided within a semiconductor wafer including an array of in-process semiconductor interposers 600'. As used herein, an “in-process” element refers to an element that is modified in material composition and/or shape in at least one subsequent processing step. The illustrated region of the wafer corresponds to a unit area UA2 of repetition in which as single in-process semiconductor interposer 600′ is provided. Each in-process semiconductor interposer 600′ may be processed into a semiconductor interposer during subsequent processing steps.

An interposer semiconductor substrate 510 is illustrated, which is a portion of the semiconductor wafer that is located within the unit area UA2 of repetition. The unit area UA2 of repetition in the semiconductor wafer is greater than unit area UA1 of repetition illustrated in FIGS. 1-6 and 8-11. An insulating layer 611 may be formed on the top surface of the interposer semiconductor substrate 510. A combination of an insulating spacer (not shown) and an interposer through-substrate via (TSV) structure 620 may be formed in each via cavity by performing material deposition processes and a planarization process (such as a chemical mechanical polishing process). Silicon-interposer metallic bump structures 654 may be formed on top surfaces of the interposer TSV structures 620. In one embodiment, a subset of the silicon-interposer metallic bump structures 654 may have a mirror image patten of the pattern of the on-interposer metal bump structures 394.

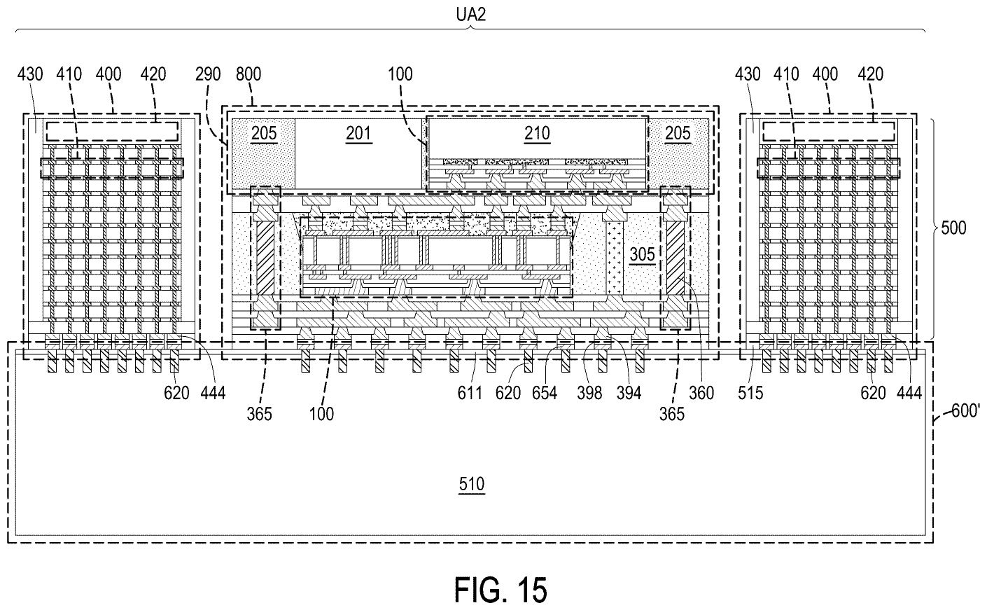

Referring to FIG. 15, a composite package 800 illustrated in FIG. 13 may be bonded to an in-process semiconductor interposer 600′ within each unit area UA2 of the semiconductor wafer. Additional semiconductor dies or additional semiconductor packages may be bonded to the in-process semiconductor interposer 600′ concurrently with, prior to, or after, bonding the composite package 800 to the in-process semiconductor interposer 600′. For example, at least one memory die 400 such as at least one high bandwidth memory (HBM) memory die may be provided. Each HBM memory die may comprise a vertical stack of memory layers 410 and a base layer 420 containing a logic circuit for controlling operation of the memory arrays in the memory layers 410. Each of the memory die 400 may comprise memory-die bump structures 444 which are used to bond the respective memory die 400 to the in-process semiconductor interposer 600′. A molding compound frame 430 may laterally surround the vertical stack of memory layers 410 and the base layer 420. The combination of the composite package 800, the memory dies 400, and molding compound multi-die frame 505 comprises a multi-die assembly 500. The multi-die assembly 500 comprises a set of at least one logic die (such as at least one semiconductor die 210), at least one memory die 400, and at least one interposer 300, and may be bonded to the in-process semiconductor interposer 600′.

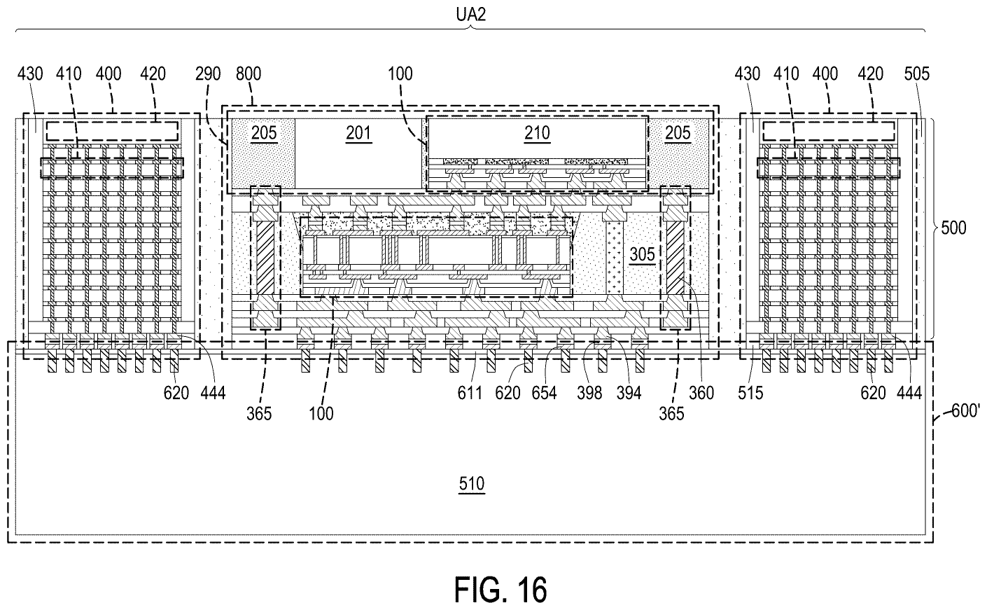

Referring to FIG. 16, underfill material portions 515 may be applied between the in-process semiconductor interposer 600′ and each of the composite package 800, the additional semiconductor dies, and the additional semiconductor packages. An encapsulant, such as a molding compound (MC) material, may be applied to the gaps among the composite package 800, the additional semiconductor dies, and the additional semiconductor packages that are bonded to the array of in-process semiconductor interposers 600′. The encapsulant may comprise any material that may be used for the molding compound die frames 205 or encapsulation frames 305 as described above. A planarization process may be performed to remove portions of the MC material that overlies the horizontal plane including the topmost surfaces of the composite package 800, the additional semiconductor dies, and the additional semiconductor packages. The top surfaces of the semiconductor dies 200 and the dummy dies 201 may be coplanar with the top surface of a remaining portion of the MC material. The remaining portion of the MC material comprises a molding compound matrix. Each portion of the molding compound matrix located within the unit area UA2 constitutes a molding compound multi-die frame 505 that laterally surrounds a plurality of semiconductor dies, and is herein referred to as a molding compound multi-die frame 505. The combination of the array of in-process semiconductor interposer 600′, the interposers 300, the memory dies 400, and the molding compound matrix constitutes a reconstituted wafer. The reconstituted wafer may comprise a two-dimensional array of reconstituted dies. Each reconstituted die may be located within a respective unit area UA2, and may comprise an in-process semiconductor interposer 600′, a composite package 800, at least one memory dies 400, and a molding compound multi-die frame 505. The illustrated portion of the exemplary structure corresponds to a unit area UA2, i.e., a region including a single repetition unit within the reconstituted wafer.

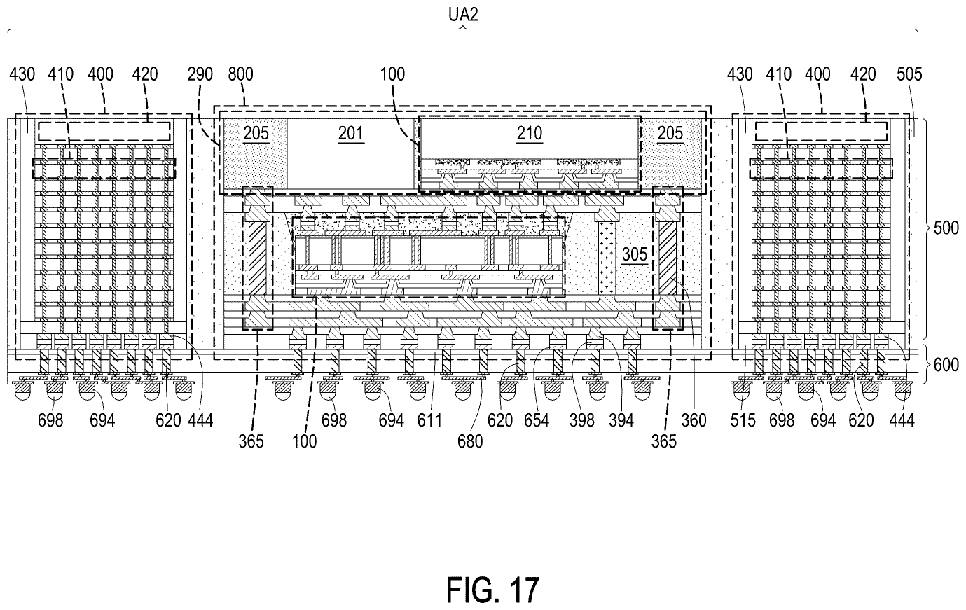

Referring to FIG. 17, the reconstituted wafer may be thinned from the backside. Specifically, the backside portion of the semiconductor wafer including the array of interposer semiconductor substrates 510 may be removed by performing a thinning process. The thinning process may use a grinding process, a polishing process, an anisotropic etch process, and/or an isotropic etch process. The thinning process may be continued until backside surfaces of the interposer TSV structures 620 are exposed. Subsequently, a backside redistribution structure may be formed on the physically exposed backside surfaces of the semiconductor wafer and the interposer TSV structures 620. The backside redistribution structure may comprise backside redistribution dielectric layer 670 and backside redistribution wiring interconnects 680.

Backside bump structures 694 may be formed on the last level of the backside redistribution wiring interconnects 680. The backside bump structures 694 may comprise microbump structures or C4 bonding pads. Solder material portions 698 may be formed on the backside bump structures 694. Upon thinning of the semiconductor wafer and upon formation of the backside redistribution structure, the backside bump structures 694, and the solder material portions 698, the in-process semiconductor interposers 600′ are converted into semiconductor interposers, which are herein referred to as semiconductor interposers 600.

The reconstituted wafer may be diced along dicing channels. Each diced portion of the reconstituted wafer comprises a system-in-package structure, which includes an assembly of a semiconductor interposer 600, a composite package 800, at least one memory die 400, and a molding compound multi-die frame 505.

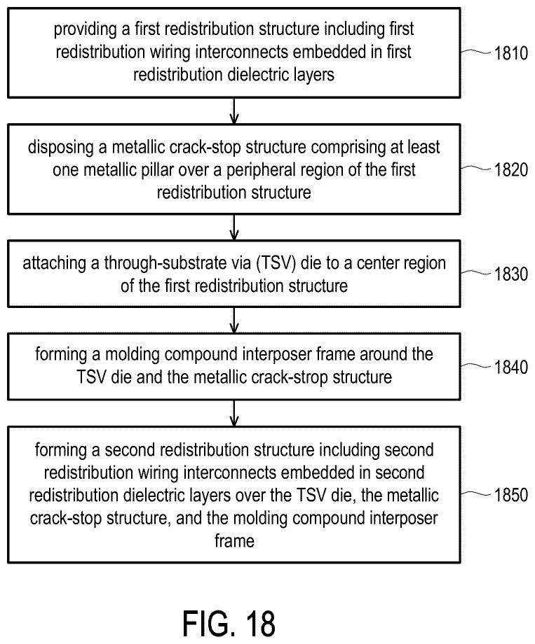

Referring to FIG. 18, a first flowchart illustrates processing steps for forming a device structure according to an embodiment of the present disclosure.

Referring to step 1810 and FIGS. 1-3, a first redistribution structure 320 including first redistribution wiring interconnects 340 formed within first redistribution dielectric layers 330 may be provided.

Referring to step 1820 and FIGS. 4 and 5, a metallic crack-stop structure 360 comprising at least one metallic pillar may be disposed over a peripheral region of the first redistribution structure 320.

Referring to step 1830 and FIGS. 6 and 7A-7J, a connection die 100 may be attached to a center region of the first redistribution structure 320.

Referring to step 1840 and FIGS. 8 and 9, an encapsulation frame 305 may be formed around the connection die 100 and the metallic crack-stop structure 360.

Referring to step 1850 and FIGS. 10-17, a second redistribution structure 390 including second redistribution wiring interconnects 380 formed within second redistribution dielectric layers 370 may be formed over the connection die 100, the metallic crack-stop structure 360, and the encapsulation frame 305.

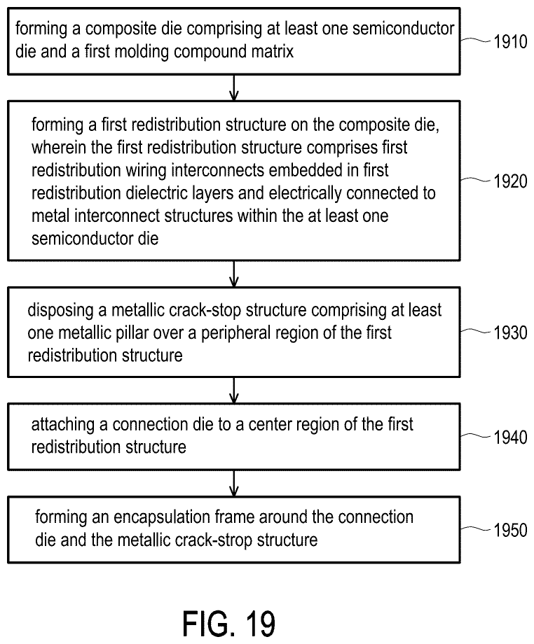

Referring to FIG. 19, a second flowchart illustrates processing steps for forming a device structure according to an embodiment of the present disclosure.

Referring to step 1910 and FIGS. 1 and 2, a composite die 290 comprising at least one semiconductor die 200 and a molding compound die frame 205 is formed.

Referring to step 1920 and FIG. 3, a first redistribution structure 320 may be formed on the composite die 290. The first redistribution structure 320 comprises first redistribution wiring interconnects 340 formed within first redistribution dielectric layers 330 and electrically connected to metal interconnect structures 222 within the at least one semiconductor die 200.

Referring to step 1930 and FIGS. 4 and 5, a metallic crack-stop structure 360 comprising at least one metallic pillar may be disposed over a peripheral region of the first redistribution structure 320.

Referring to step 1940 and FIGS. 6 and 7A-7J, a connection die 100 may be attached to a center region of the first redistribution structure 320.

Referring to step 1950 and FIGS. 8-17, an encapsulation frame 305 may be formed around the connection die 100 and the metallic crack-stop structure 360.

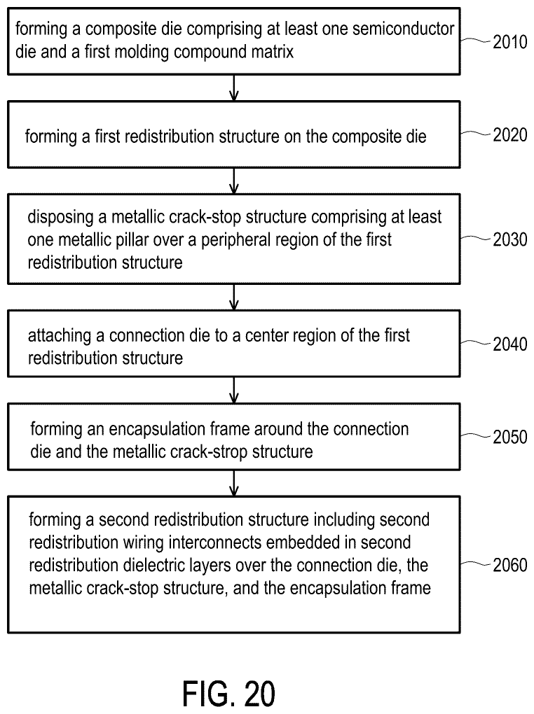

Referring to FIG. 20, a third flowchart illustrates processing steps for forming a device structure according to an embodiment of the present disclosure.

Referring to step 2010 and FIGS. 1 and 2, a composite die 290 comprising at least one semiconductor die 200 and a molding compound die frame 205 is formed.

Referring to step 2020 and FIG. 3, a first redistribution structure 320 may be formed on the composite die 290.

Referring to step 2030 and FIGS. 4 and 5, a metallic crack-stop structure 360 comprising at least one metallic pillar may be disposed over a peripheral region of the first redistribution structure 320.

Referring to step 2040 and FIGS. 6 and 7A-7J, a connection die 100 may be attached to a center region of the first redistribution structure 320.

Referring to step 2050 and FIGS. 8 and 9, an encapsulation frame 305 may be formed around the connection die 100 and the metallic crack-stop structure 360.

Referring to step 2060 and FIGS. 10-17, a second redistribution structure 390 including second redistribution wiring interconnects 380 formed within second redistribution dielectric layers 370 may be formed over the connection die 100, the metallic crack-stop structure 360, and the encapsulation frame 305.

Referring to all drawings and according to various embodiments of the present disclosure, a package structure is provided, which comprises: a first redistribution structure 320 including first redistribution wiring interconnects 340 formed within first redistribution dielectric layers 330; a metallic crack-stop structure 360 comprising at least one metallic pillar and disposed over a peripheral region of the first redistribution structure 320; a connection die 100 attached to a center region of the first redistribution structure 320; an encapsulation frame 305 embedding the connection die 100 and the metallic crack-stop structure 360; and a second redistribution structure 390 including second redistribution wiring interconnects 380 formed within second redistribution dielectric layers 370 and located over the connection die 100, the metallic crack-stop structure 360, and the encapsulation frame 305.

In one embodiment, the package structure further comprises an array of metal bump structures (such as on-interposer metal bump structures 394) located on the second redistribution wiring interconnects 380, wherein the metallic crack-stop structure 360 is electrically isolated from the array of metal bump structures.

In one embodiment, the first redistribution structure 320 comprises a first edge-seal ring structure (340E, 354E) that continuously extends along a peripheral region of the first redistribution structure 320 and vertically extends from a bottommost one of the first redistribution dielectric layers 330 to a topmost one of the first redistribution dielectric layers 330; and the metallic crack-stop structure 360 is electrically connected to the first edge-seal ring structure (340E, 354E).

In one embodiment, the second redistribution structure 390 comprises a second edge-seal ring structure 380E that continuously extends along a peripheral region of the second redistribution structure 390 and vertically extends from a bottommost one of the second redistribution dielectric layers 370 to a topmost one of the second redistribution dielectric layers 370; and the metallic crack-stop structure 360 is electrically connected to the second edge-seal ring structure 380E.

In one embodiment, a top surface of the encapsulation frame 305, a top surface of the connection die 100, and a top surface of the metallic crack-stop structure 360 are located within a horizontal plane including a bottommost surface of the second redistribution structure 390.

In one embodiment, the first redistribution structure 320 comprises first bump structures 3541 in the center region; the connection die 100 comprises connection-die bump structures; and the connection die 100 is attached to the first redistribution structure 320 through a solder-mediated bonding between the connection-die bump structures and the first bump structures 3541.

In one embodiment, the first redistribution structure 320 further comprises second bump structures 3542; through-interposer via (TIV) structures 350 are located on the second bump structures 3542 and are embedded within the encapsulation frame 305; the TIV structures are electrically connected to a respective one of the first redistribution wiring interconnects 340; and the TIV structures are electrically connected to a respective one of the second redistribution wiring interconnects 380.

The foregoing outlines features of several embodiments so that those skilled in the art may better understand the aspects of the present disclosure. Each embodiment described using the term “comprises” also inherently discloses that the term “comprises” may be replaced with “consists essentially of” or with the term “consists of” in some embodiments, unless expressly disclosed otherwise herein. Whenever two or more elements are listed as alternatives in a same paragraph or in different paragraphs, a Markush group including a listing of the two or more elements may also be impliedly disclosed. Whenever the auxiliary verb “may” is used in this disclosure to describe formation of an element or performance of a processing step, an embodiment in which such an element or such a processing step is not performed is also expressly contemplated, provided that the resulting apparatus or device may provide an equivalent result. As such, the auxiliary verb “may” as applied to formation of an element or performance of a processing step should also be interpreted as “may” or as “may, or may not” whenever omission of formation of such an element or such a processing step is capable of providing the same result or equivalent results, the equivalent results including somewhat superior results and somewhat inferior results. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of forming a device structure comprising:
providing a first redistribution structure including first redistribution wiring interconnects formed within first redistribution dielectric layers;
disposing a metallic crack-stop structure comprising at least one metallic pillar over a peripheral region of the first redistribution structure;
attaching a connection die to a center region of the first redistribution structure;
forming an encapsulation frame around the connection die and the metallic crack-stop structure; and
forming a second redistribution structure including second redistribution wiring interconnects formed within second redistribution dielectric layers over the connection die, the metallic crack-stop structure, and the encapsulation frame.

2. The method of claim 1, further comprising forming an array of metal bump structures on the second redistribution wiring interconnects, wherein the metallic crack-stop structure is electrically isolated from the array of metal bump structures.

3. The method of claim 1, wherein:
the first redistribution structure comprises a first edge-seal ring structure that continuously extends in the peripheral region of the first redistribution structure and vertically extends from a bottommost one of the first redistribution dielectric layers to a topmost one of the first redistribution dielectric layers; and
the metallic crack-stop structure is electrically connected to the first edge-seal ring structure.

4. The method of claim 3, wherein:
the second redistribution structure comprises a second edge-seal ring structure that continuously extends along a peripheral region of the second redistribution structure and vertically extends from a bottommost one of the second redistribution dielectric layers to a topmost one of the second redistribution dielectric layers; and
the metallic crack-stop structure is electrically connected to the second edge-seal ring structure.

5. The method of claim 1, wherein the encapsulation frame is formed by:
applying a molding compound material around the connection die and the metallic crack-stop structure; and
performing a planarization process that removes a portion of the molding compound material from above a planarization horizontal plane such that top surfaces of the connection die and the metallic crack-stop structure are physically exposed at the planarization horizontal plane after the planarization process, wherein a remaining portion of the molding compound material comprises the encapsulation frame.

6. The method of claim 1, wherein:
the connection die comprises a through-substrate-via-containing (TSV-containing) die;
the first redistribution structure comprises first bump structures in the center region;
the TSV-containing die comprises connection-die bump structures; and
the TSV-containing die is attached to the first redistribution structure through a solder-mediated bonding between the connection-die bump structures and the first bump structures.

7. The method of claim 6, wherein:
the first redistribution structure further comprises second bump structures; and
the method comprises disposing through-interposer via (TIV) structures on the second bump structures, wherein the encapsulation frame is formed around the TIV structures.

8. The method of claim 7, wherein:
the TIV structures are electrically connected to a respective one of the first redistribution wiring interconnects upon disposition on the second bump structures; and
the TIV structures are electrically connected to a respective one of the second redistribution wiring interconnects upon formation of the second redistribution wiring interconnects.

9. A method of forming a device structure comprising:
forming a composite die comprising at least one semiconductor die and a first molding compound matrix;
forming a first redistribution structure on the composite die, wherein the first redistribution structure comprises first redistribution wiring interconnects formed within first redistribution dielectric layers and electrically connected to metal interconnect structures within the at least one semiconductor die;
disposing a metallic crack-stop structure comprising at least one metallic pillar over a peripheral region of the first redistribution structure;
attaching a connection die to a center region of the first redistribution structure; and
forming an encapsulation frame around the connection die and the metallic crack-stop structure.

10. The method of claim 9, wherein:
the first redistribution structure comprises first bump structures located in a center region and at least one peripheral bump structure located in the peripheral region and having a same material composition as the first bump structures;
each top surface of the at least one peripheral bump structure and top surface of the first bump structures are formed within a same horizontal plane;
the connection die is bonded to the first bump structures via an array of solder material portions; and
the at least one metallic pillar is disposed directly on the at least one peripheral bump structure.

11. The method of claim 9, wherein:
the connection die comprises a through-substrate-via-containing (TSV-containing) die;
the metallic crack-stop structure comprises a plurality of metallic pillars that are laterally spaced from one another; and
the TSV-containing die is laterally enclosed by the metallic crack-stop structure upon attachment to the center region of the first redistribution structure.

12. The method of claim 9, wherein the metallic crack-stop structure comprises a rectangular frame that overlies the peripheral region of the first redistribution structure.

13. The method of claim 9, further comprising forming a second redistribution structure including second redistribution wiring interconnects formed within second redistribution dielectric layers over the connection die, the metallic crack-stop structure, and the encapsulation frame.

14. A package structure comprising:
a first redistribution structure including first redistribution wiring interconnects formed within first redistribution dielectric layers;
a metallic crack-stop structure comprising at least one metallic pillar and disposed over a peripheral region of the first redistribution structure;
a connection die attached to a center region of the first redistribution structure;
an encapsulation frame embedding the connection die and the metallic crack-stop structure; and
a second redistribution structure including second redistribution wiring interconnects formed within second redistribution dielectric layers and located over the connection die, the metallic crack-stop structure, and the encapsulation frame.

15. The package structure of claim 14, further comprising an array of metal bump structures located on the second redistribution wiring interconnects, wherein the metallic crack-stop structure is electrically isolated from the array of metal bump structures.

16. The package structure of claim 14, wherein:
the first redistribution structure comprises a first edge-seal ring structure that continuously extends along a peripheral region of the first redistribution structure and vertically extends from a bottommost one of the first redistribution dielectric layers to a topmost one of the first redistribution dielectric layers; and
the metallic crack-stop structure is electrically connected to the first edge-seal ring structure.

17. The package structure of claim 16, wherein:
the second redistribution structure comprises a second edge-seal ring structure that continuously extends along a peripheral region of the second redistribution structure and vertically extends from a bottommost one of the second redistribution dielectric layers to a topmost one of the second redistribution dielectric layers; and
the metallic crack-stop structure is electrically connected to the second edge-seal ring structure.

18. The package structure of claim 14, wherein a top surface of the encapsulation frame, a top surface of the connection die, and a top surface of the metallic crack-stop structure are located within a horizontal plane including a bottommost surface of the second redistribution structure.

19. The package structure of claim 14, wherein:
the connection die comprises a through-substrate-via-containing (TSV-containing) die;
the first redistribution structure comprises first bump structures in the center region;
the TSV-containing die comprises connection-die bump structures; and
the TSV-containing die is attached to the first redistribution structure through a solder-mediated bonding between the connection-die bump structures and the first bump structures.

20. The package structure of claim 14, wherein:
the first redistribution structure further comprises second bump structures;
through-interposer via (TIV) structures are located on the second bump structures and are embedded within the encapsulation frame;
the TIV structures are electrically connected to a respective one of the first redistribution wiring interconnects; and
the TIV structures are electrically connected to a respective one of the second redistribution wiring interconnects.
